(19) United States
(12) Patent Application Publication
(10) Pub. No.: US 2022/0223429 A1
(43) Pub. Date: Jul. 14, 2022

(54) N-POLAR III-N SEMICONDUCTOR DEVICE STRUCTURES

(71) Applicant: The Regents of the University of California, Oakland, CA (US)

(72) Inventors: Brian Romanczyk, Santa Barbara, CA (US); Emmanuel Kayede, Santa Barbara, CA (US); Wenjian Liu, Santa Barbara, CA (US); Islam Sayed, Goleta, CA (US); Umesh K. Mishra, Montecito, CA (US)

(73) Assignee: The Regents of the University of California, Oakland, CA (US)

(21) Appl. No.: 17/352,139

(22) Filed: Jun. 18, 2021

Related U.S. Application Data
(60) Provisional application No. 63/040,705, filed on Jun. 18, 2020.
(60) Provisional application No. 63/040,674, filed on Jun. 18, 2020.

(51) Int. Cl. H01L 21/306; H01L 29/20; H01L 29/205; H01L 29/47; H01L 29/778; H01L 29/872; H01L 21/285; H01L 21/308; H01L 29/66; H01L 29/34

(52) U.S. Cl. CPC H01L 21/30612; H01L 29/2003; H01L 29/205; H01L 29/475; H01L 29/7786; H01L 29/34; H01L 21/28581; H01L 21/28587; H01L 21/308; H01L 29/66212; H01L 29/66462; H01L 29/872

(57) ABSTRACT

N-polar transistor structures have relied on the use of dry etch processes that use plasmas generated from gaseous species to remove III-N layers as commercially viable wet etchants do not exist. The present disclosure reports on methods for the fabrication of N-polar III-N transistors using wet etches along with transistor structures that are enabled by the availability of wet-etches.

### CROSS REFERENCE TO RELATED APPLICATIONS

This application claims the benefit under 35 U.S.C. Section 119(e) of co-pending and commonly-assigned U.S. provisional patent application Serial Nos:

63/040,705, filed on Jun. 18, 2020, by Brian Romanczyk, Umesh K. Mishra, and Emmanuel Kayede, entitled “N-POLAR III-N SEMICONDUCTOR DEVICE STRUCTURES ENABLED BY WET CHEMISTRY,” Attorney Docket 30794.778USP1 (UC Ref. 2020-703); and

63/040,674, filed on Jun. 18, 2020, by Umesh K. Mishra, Wenjian Liu, Islam Sayed, and Brian Romanczyk, entitled “DEVICE STRUCTURES UTILIZING BARRIER ENHANCEMENT CONDUCTIVE MATERIALS ON N-POLAR III-NITRIDES,” Attorney Docket 30794.780USP1 (UC Ref 2020-710),

both of which applications are incorporated by reference herein.

### STATEMENT REGARDING FEDERALLY SPONSORED RESEARCH AND DEVELOPMENT

This invention was made with Government support under Grant (or Contract) No. N00014-20-1-2166, awarded by the United States Office of Naval Research. The Government has certain rights in this invention.

### BACKGROUND OF THE INVENTION

### 1. Field of the Invention. The present disclosure relates to N-Polar III-nitride devices and methods of making the same.

### 2. Description of the Related Art.

(Note: This application references a number of different references as indicated throughout the specification by one or more reference numbers in superscripts, e.g., ^{[x]}. A list of these different publications ordered according to these reference numbers can be found below in the section entitled “References.” Each of these publications is incorporated by reference herein.

### SUMMARY OF THE INVENTION

During the fabrication of semiconductor devices, materials are deposited and etched away in a controlled fashion to form the device. The III-N crystals are generally considered to be chemically inert. This has particularly been the case for metal-polar III-N materials where transistor structures fabricated in this orientation have relied on the use of dry etch processes that use plasmas generated from gaseous species to remove III-N layers as commercially viable wet etchants do not exist. While metal-polar III-N surfaces are known to be chemically stable, the N-polar surface is more reactive. A first embodiment of the present invention takes advantage of these properties to the N-polar surface and has developed methods for the fabrication of N-polar III-N transistors using wet etches along with transistor structures that are enabled by the availability of wet-etches.

A second embodiment of the present invention utilizes conductive materials to improve electrical interfaces in N-polar devices. Conductive materials on semiconductors have electron barriers (i.e. Schottky barrier between metal and semiconductors) that are classically described based on the energy difference between the work function of the conductive material and the electron affinity of the semiconductor. In N-polar III-nitrides systems, phenomena are known to exist which reduce this barrier height. However, a device having conductive materials on N-polar III-nitrides with barrier heights greater than this difference are not known. Surprisingly, the present disclosure describes devices where the conductive material on a N-polar group III-nitride semiconductor provides an enhanced barrier height greater than or equal to the difference between the work function and electron affinity. As described herein, the barrier enhancement can be used to improve the performance of various N-polar III-nitride devices.

Example embodiments include, but are not limited to, the following.

1. A method of making a device, comprising:

obtaining an N-polar III-N layer having a surface, wherein the surface has a starting surface roughness; and

etching the surface, wherein the etching comprises wet etching using a wet etchant such that a final surface roughness of the surface, formed by the wet etching, is not increased by more than a factor of 3 as compared to the starting surface roughness, and the final surface roughness is below 3.0 nanometers (nm) root mean square (rms) roughness.

2. The method of clause 1, wherein the etching comprises at least one of:
(a) the wet etching using the wet etchant comprising aqueous citric acid at a temperature above room temperature;
(b) etching using sequential cycles of O₂ plasma treatment and the wet etching using the wet etchant comprising citric acid ;
(c) the wet etchant comprising ammonium sulfide;
(d) the wet etchant comprising a mixture of phosphoric acid, nitric acid, acetic acid, and water;
(e) the wet etchant comprising an aqueous mixture of HCl; or
(f) the wet etchant comprising an aqueous mixture of HBr.

3. The method of clause 2, wherein:

the wet etchant comprising aqueous citric acid further comprises H₂O₂, or

the wet etchant comprising HCL further comprises HNO₃, or

the wet etchant comprising HBr further comprises HNO₃

4. A method of making an N-polar III-N device, comprising at least one of:

performing a wet etch that etches one or more N-polar III-N layers, wherein the wet etch uses a solution comprising a first etchant that etches AlₓGa₁₋ₓN faster than Al_{y}Ga_{1-y}N where x is less than y,

performing a wet etch that etches one or more N-polar III-N layers, wherein the wet etch uses a solution comprising a second etchant that etches AlₓGa₁₋ₓN faster than Al_{y}Ga_{1-y}N where x is greater than y , or

digitally etching one or more of the N-polar III-N layers using a dry oxidation step exposing the one or more layers to an oxidizer so as to form an oxidized surface layer; and then wet etching the oxidized surface layer using an etchant that etches the oxidized surface layer at least 10 times faster than the underlaying layer.

5. The method of clause 4, wherein the solution comprising the first etchant includes a mixture containing an inorganic acid as an active ingredient.

6. The method of clause 5, wherein the mixture comprises an aqueous mixture of at least one of HCl or HBr.

7. The method of clause 4, further comprising adding an additional component comprising at least one of HNO₃ or H₂O₂ to the solutions to tune an etch property of the wet etching.

8. The method of clause 4, wherein the solution comprising the second etchant includes a mixture containing an organic acid as an active ingredient.

9. The method of clause 8, wherein the mixture comprises an aqueous mixture of at least one of citric acid or phosphoric acid.

10. The method of clause 4, wherein the layers comprise a doping profile that increases the preferential etching:

of the first etchant, increasing the etch rate of the AlₓGa₁₋ₓN as compared to the Al_{y}Ga_{1-y}N when x is less than y, or of the second etchant, increasing the etch rate of the AlₓGa₁₋ₓN as compared to the Al_{y}Ga_{1-y}N when x is greater than y.

11. The method of clause 4, comprising:

obtaining the III-Nitride N-polar layers comprising a nitride barrier layer comprising aluminum, a GaN channel layer on or above the nitride barrier layer; a nitride cap layer comprising aluminum on or above the GaN channel layer; and a GaN cap layer on or above the nitride cap layer; and

etching one or more of the layers, comprising wet etching using one or more solutions comprising at least one of the first etchant or the second etchant.

12. The method of clause 11, wherein:

the device comprises a high electron mobility transistor, and

the method further comprises depositing an etch mask on the GaN cap layer,

the wet etching etches the recess comprising a gate recess through the GaN cap layer, forming a lateral undercut in the etch mask, and

the method further comprises depositing gate metal in the gate recess, wherein the lateral undercut allows deposition of the gate metal in a self-aligned manner and reduces or eliminates deposition of the gate metal on sidewalls of the GaN cap layer.

13. The method of clause 11, wherein:

the device comprises a high electron mobility transistor, and

the wet etching etches at least one of:

a recess through part of the GaN cap layer that does not expose the nitride cap layer

a recess through the GaN cap layer that exposes the nitride cap layer, or

a thickness through the GaN cap layer and the nitride cap layer so as to expose the GaN channel layer.

14. The method of clause 13, wherein the wet etching forms the gate recess exposing a wet etched surface of the nitride cap layer, the method further comprising: depositing gate metal on the wet etched surface so as to form an electrical interface with the wet etched surface, the electrical interface comprising a Schottky barrier, the electrical interface comprising at least one of:

a higher Schottky barrier height by 0.1 eV or more or

a reduced gate leakage by a factor of 10 or more,

relative to a dry-etched or non-wet-etch treated surface, and such that the gate metal forms a gate with an absolute gate leakage below 1 mA/mm at a drain voltage at or below 0.5 V and a gate voltage corresponding to 1 milliamp/millimeter of drain current .

15. The method of clause 14, wherein the gate metal comprises ruthenium metal or an alloy containing greater than 20% ruthenium metal and forms a barrier height greater than 0.6 eV to the nitride cap layer.

16. The method of clause 13, wherein the wet etching forms the recess comprising a gate recess and exposes an N-polar wet etched surface of the nitride cap layer, the method further comprising:

depositing a dielectric layer in the recess and on the nitride cap layer, wherein an electrical N-polar-dielectric interface, between the dielectric layer and the N-polar wet etched surface, has a reduced number of interface states by a factor of 2 or more as compared to when the interface is formed using dry etching and with an overall density of interface states below 5×10¹² cm⁻²eV⁻¹.

17. The method of clause 12, wherein the wet etching etches a thickness of the GaN cap layer so that the GaN cap layer is thinner on one side of the gate recess than the other.

18. The method clause 17, comprising a T-shaped gate metal in the recess and wherein the T-shaped gate metal is used as a mask during the wet etching.

19. A diode or transistor device, comprising:

an N-polar group III-nitride semiconductor; and

a conductive material on or above the semiconductor and forming an interface between the conductive material and the N-polar group III-nitride semiconductor, wherein:

a barrier height comprising a conduction band difference between the N-polar III-nitride semiconductor and the conductive material at/near the interface is larger than the difference between the work function of the conductive material and the electron affinity of the N-polar group III-Nitride semiconductor, wherein the conductive material forms a Schottky barrier between the semiconductor and the conductive material.

20. The device of clause 19, wherein the conductive material comprises ruthenium metal or an alloy containing greater than 20% ruthenium metal and forms a barrier height greater than 0.6 eV to the N-polar III-nitride semiconductor.

### BRIEF DESCRIPTION OF THE DRAWINGS

Referring now to the drawings in which like reference numbers represent corresponding parts throughout:

FIGS. 1A-1C. SEM micrographs showing roughened N-polar GaN surfaces that have been exposed to NH₄OH (FIG. 1A), HCl (FIG. 1B), and NaOH (FIG. 1C). The induced roughness makes these chemistries incompatible for a gate recess etch.

FIG. 2. AFM height image of a UID N-polar GaN film etched in 80° C. citric acid for 2 hours.

FIG. 3. Fabrication process flow of a N-polar GaN deep recess HEMT. Plasma etches of III-N layers are currently used within steps 2, 4, 5, and 8.

FIG. 4. Etch rate of N-polar GaN in the BCl₃/SF₆ selective etch. A mean etch rate of 14.7 nm/min has been observed with a standard deviation of 2.7 nm/min.

FIGS. 5A-5C. Formation of an asymmetric GaN cap recess etch, wherein FIG. 5A shows an etch mask can protect the one half of the device (drain side protected shown) using the T-gate head to assist in alignment tolerance, FIG. 5B shows the result of a thinned GaN cap on the source side, and FIG. 5C shows the inverse structure with the drain side etched.

FIGS. 6A-6B. Formation of gates with partial metal coverage of the GaN cap sidewall. FIG. 6A shows using wet etches which etch laterally as well as vertically leads to an undercut of the etch mask. FIG. 6B shows this etch mask can be used to control the placement of the gate metal where metal can cover the base of the recess but not the sidewalls.

FIGS. 7A-7C. A reduction in defects at gate interfaces by wet etch treatments allow for multiple options to improve the gate. FIG. 7A shows treatment prior to the gate dielectric deposition. FIG. 7B shows increased Schottky barrier height allows for the removal of the gate dielectric. FIG. 7C shows a regrown gate barrier such as high composition AlGaN or p-GaN provides a better barrier without sacrificing the performance of the access region.

FIG. 8A shows Planar N-polar GaN high electron mobility (HEMT) and FIG. 8B shows deep recess N-polar GaN HEMT where the gated surface is modified prior to the deposition of the gate metal to expose crystal planes other than the N-polar plane. Leakage through dislocations (shown as vertical dashed lines) is reduced improving the barrier quality.

FIG. 9. Formation of selective area n-type regions by wet-etching and mass-reflow. (a) Starting N-polar GaN HEMT with patterned SiO2 mask. (b) Wet etching of N-polar GaN to form roughened regions where the openings in the SiO₂ exist. (c) Thermal treatment during which the roughened regions reflow and incorporate dopants from the SiO₂ mask forming n-type regions.

FIG. 10. Barrier height values from I-V and reverse leakages (unit: A/cm²) of metals on N-polar GaN [3-6].

FIG. 11. (a) The cross-sectional schematic and (b) the conduction band energy diagram of A-A′ region in a device utilizing barrier enhancement conductive materials on N-polar III-nitrides.

FIG. 12. Circular diode structure.

FIG. 13. Interdigitated diode structure.

FIG. 14. Planar transistor structure.

FIG. 15. Recessed transistor structure.

FIG. 16. The fabrication procedure of Ru/N-polar GaN Schottky diodes: (a) N-polar GaN epitaxial structure; (b) the formation of Ru/Pt/Au Schottky gate electrode; (c) the Schottky diode device structure.

FIG. 17. The current-voltage curve giving an enhanced barrier 0.77 eV and ˜10⁻⁶A/cm² reverse leakage at −5 V

FIG. 18. Temperature dependent DC I-V curves under forward bias and reverse bias at temperatures from 298 K to 448 K with 25 K per step.

FIG. 19. At various temperatures, barrier height from forward bias region ϕB, Forward and reverse bias region ϕB, Reverse (left y-axis); ideality factor n (right y-axis).

FIG. 20. Flowchart illustrating a method of manufacturing a device.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

I. N-polar III-N Semiconductor Device Structures Enabled by Wet Chemistry

This disclosure covers both fabrication methods and device structures that can be realized using wet chemical etching of N-polar III-N materials. Certain etchants create smooth surfaces, others create roughened surfaces. Both of these characteristics can be used to improve the performance and/or manufacturability of N-polar devices.

A. Methods for Wet-Etching N-Polar GaN

1. Chemical Reactivity of N-Polar GaN

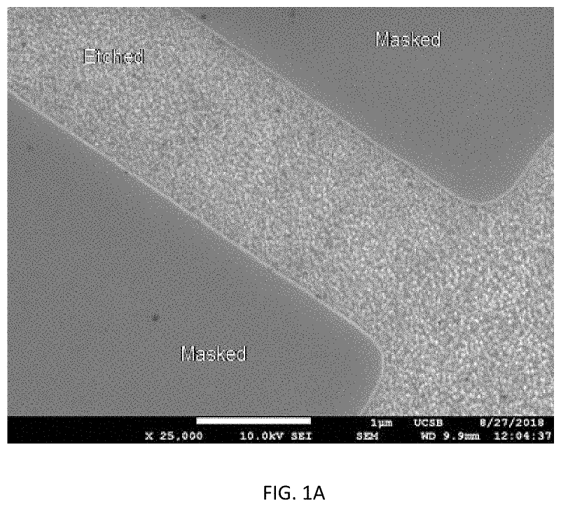

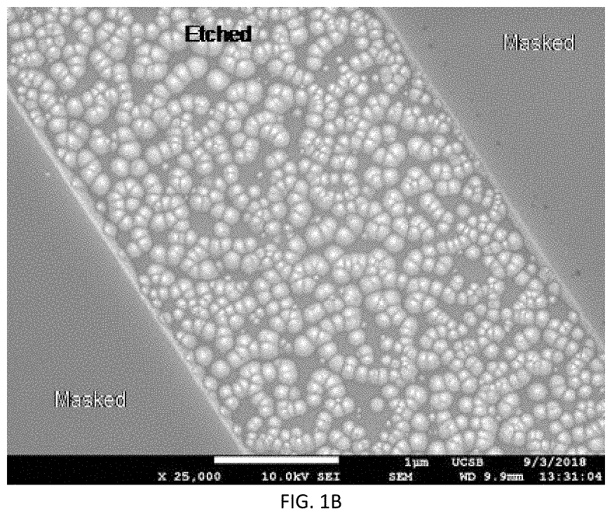

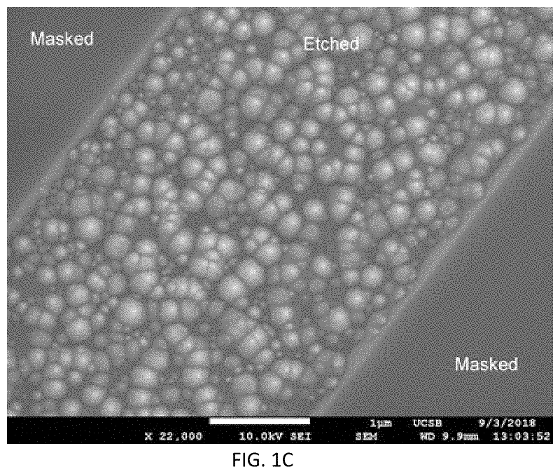

The reactivity of N-polar GaN in certain solutions is well known. For instance, strong basic solutions such as KOH have been used in the fabrication of light-emitting diodes (LEDs) to create a significantly roughened surface for enhanced light extraction. Similarly, roughened surfaces have also been observed from aqueous solutions of NaOH, NH₄OH, TMAH, and HCl (FIG. 1). In the fabrication of transistors however, there are parts of the fabrication process where the degree of surface roughening observed in these solutions is too extreme and a smoother etched surface is desired. Therefore, alternate etch chemistries are needed. Until now, a smoothly etched N-polar surface has not been demonstrated.

2. Citric Acid Etching of N-Polar GaN

In the III-As system, multiple wet etches are employed in the fabrication of devices. One particular etch system based on citric acid (CH₂COOH-C(OH)COOH-CH₂COOH) has commonly been used for the gate recess etch for the fabrication of III-As HEMTs because this etch system has the following advantages:

i. providing a smooth etched surface,

ii. demonstrated more than 100:1 selectivity between GaAs and AlGaAs [1], and

iii. is compatible with photoresists.

Furthermore, citric acid-based gate recess etches have continued to be employed even for the most highly scaled THz-class InP HEMTs (L_{G}=25 nm) [2].

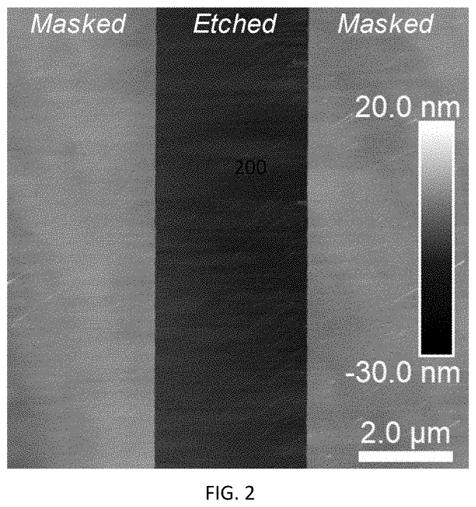

While it has previously been reported [3] that Ga-polar GaN does not etch in citric acid even at an elevated temperature of 75° C., our preliminary investigations of N-polar in citric acid solutions indicate that a smoothly-etched surface can be obtained. FIG. 2 shows an atomic force microscope (AFM) image of an unintentionally-doped (UID) N-polar GaN sample that was etched in an 80° C. citric acid solution for two hours. 11.5 nm of GaN was etched in that time with no difference in the root mean square (rms) roughness between the etched and unetched regions of the sample. This etch has also demonstrated selectivity. UID N-polar GaN etches about 4 times slower than UID N-polar Al_{0.24}Ga_{0.76}N films. Mg-doped p-type GaN films etch about 2 times slower than UID N-polar GaN. Similar results have also been obtained using the commercially available mixture, Al Etch Type A, from Transene Company, Inc. which is comprised of phosphoric acid, nitric acid, acetic acid, and water.

An alternate approach has also been demonstrated using a digital etch technique. Cyclical exposure to an O₂ plasma (1 min) followed by submersion in citric acid at room temperature (2 min) etched UID N-polar GaN at a rate of 1.0 nm/cycle with no degradation in rms roughness. The success of this digital technique provides guidance on the development of other etches as this shows that the oxidation process is the limiting step. The accurate control of the etch rate in a digital etch make such an etch ideal for the removal of thin layers where accuracy of the etch depth is needed and the number of cycles needed to reach that etch depth is not too large. While a pure wet-etch chemistry etch technique would eliminate all plasma exposure, it has been demonstrated that the digital etching of Ga-polar GaN using the same system for O₂ plasma treatment but with HCl as the dissolution acid indicated that a digital etch with O₂ plasma was superior to a Cl₂ RIE gate recess etch [4]. In that work the gate leakage for a digitally etched HEMT was slightly lower than an unetched barrier and more than 1000× lower than a HEMT with a Cl₂ RIE gate recess.

3. Hydrochloric Acid—Nitric Acid Etching of N-Polar GaN

While HCl or HCl diluted with H₂O has demonstrated large pyramidal features after etching (FIG. 1(b)) with the addition of nitric acid to this solution the number and size of these pyramids has been shown to be reduced (for instance with 1:5:1 HCl:HNO₃:H₂O). Furthermore, N-polar Al_{0.24}Ga_{0.76}N does not readily etch in this solution. This was observed at, or near, room temperature. This establishes that GaN can be etched while selectively stopping on AlGaN layers.

4. Techniques Demonstrated to Etch N-Polar GaN without Significant Degradation to the Surface
Aqueous Citric Acid at temperatures above room temperature which may also contain other components such as H₂O₂.
Sequential Cycles of O₂ plasma treatment and Mixtures of Citric Acid at room temperature
Ammonium Sulfide
Aluminum Etch Type A—A commercially available mixture of phosphoric acid, nitric acid, acetic acid, and water from Transene Company, Inc.
Aqueous mixtures of HCl which may also contain other components such as HNO₃
Aqueous mixtures of HBr which may also contain other components such as HNO₃

The present disclosure has surprisingly that unexpectedly discovered that these wet etchants can be used to wet etch a smooth surface of N-polar III-N materials (e.g., less than 3 nm rms surface roughness).

5. Techniques Demonstrated to Etch N-Polar GaN preferentially over AlGaN
Aqueous mixtures of HCl which may also contain other components such as HNO₃
Aqueous mixtures of HBr which may also contain other components such as HNO₃

6. Techniques Demonstrated to Etch N-Polar AlGaN preferentially over GaN
Aqueous Citric Acid at temperatures above room temperature which may also contain other components such as H₂O₂
Mixtures Containing Phosphoric Acid, such as Aluminum Etch Type A

7. Additional Comments on Choice and Composition of Etch Chemistry
While citric acid has been demonstrated to smoothly etch N-polar GaN we view this invention to cover any liquid solution which provides a quality electrical surface. A quality electrical surface may also be realized with a slightly roughened surface where crystal planes other than the N-polar (000-1) plane are exposed.
Citric Acid in the above mixtures can likely be replaced by similar carboxylic acids such as Oxalic, Succinic, Formic, Acetic acids.
Adjusting the pH of the solution or buffering the solution is also likely to impact the etch rate, selectivity, and surface roughness.
Changing the solution temperature, adding illumination and/or electrochemical etch to impart energy into the system may be used with any of the etches to tune properties.
Based on the observed selectivity we observe that mineral acids (HCl, HBr) provide selectivity where GaN is etched preferentially over AlGaN. Other mineral acids may also provide this selectivity. Preferential etching of AlGaN over GaN has been demonstrated by organic acids (Citric, Phosphoric). Therefore other organic acids may provide similar preferential etching.

8. Comments on the Etching Methodology
The demonstrated etches were performed by submerging a sample is a beaker of solution without agitation. Nothing prevents the use of other etching techniques such as adding in agitation (such as by stirring, using a circulating bath, and/or adding in sonication) or using a spray etcher in regard to this invention.

B. Device Structures Enabled by Wet Chemical Etching

1. Deep Recess N-Polar GaN HEMT

N-polar GaN deep recess HEMTs have recently demonstrated significant advantages over Ga-polar GaN HEMTs enabling greatly improved mm-wave power performance using a recessed gate structure [5, 6]. While this device has demonstrated excellent performance there are aspects of the fabrication process that are limited by the current use of dry etches.

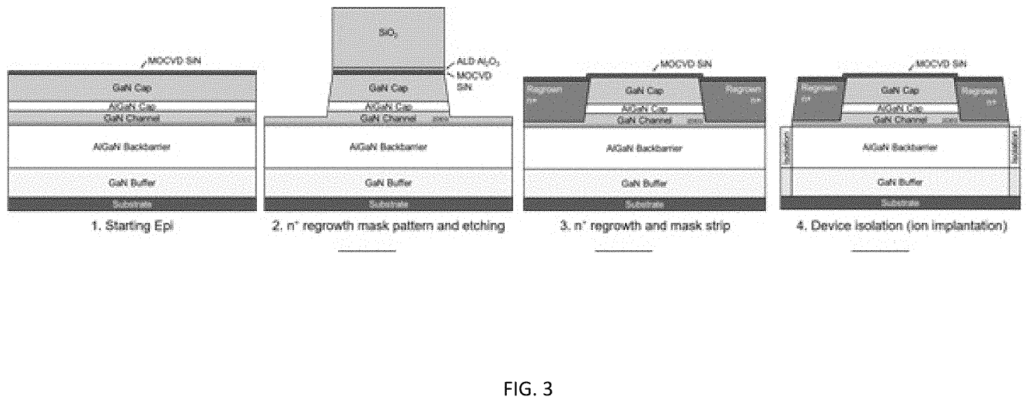

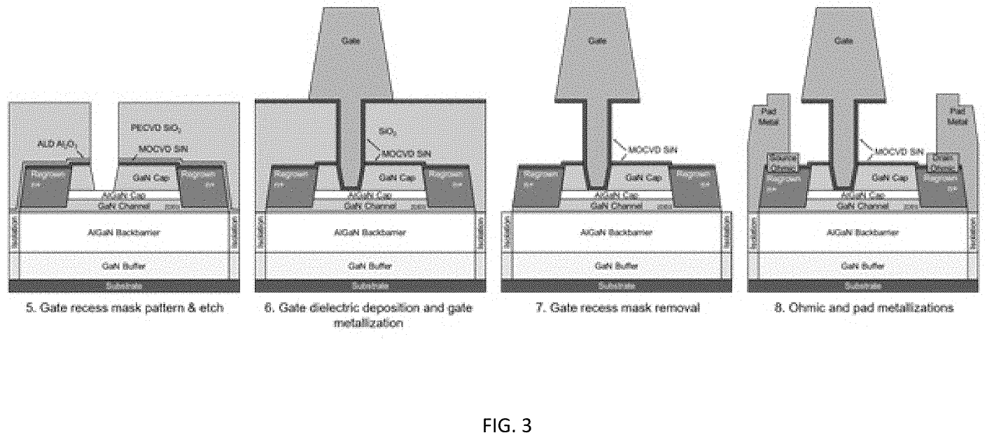

FIG. 3 shows a schematic overview of the process flow for a deep recess N-polar HEMT. Within this process there are six separate required plasma etches of N-polar III-N layers (alignment mark etch, regrowth selective GaN cap etch, regrowth AlGaN cap etch, isolation n⁺ etch, gate recess selective GaN cap etch, and ohmic n⁺ etch).

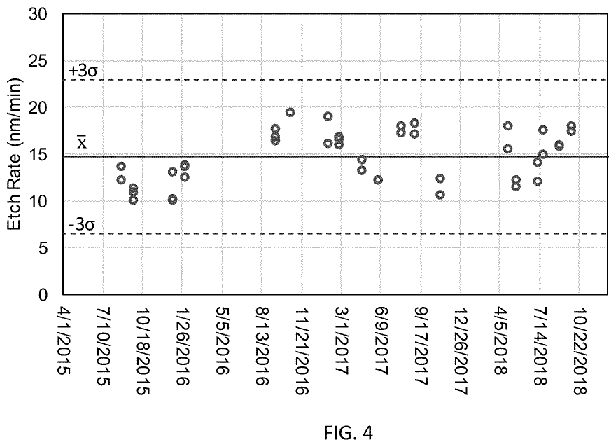

The most critical of these is the etch for to remove the GaN cap which occurs both prior to the regrowth of n⁺ source and drain contact layers as well as for the gate recess etch. The existing process uses a selective ICP etch based on a BCl₃/SF₆ gas chemistry which provides ˜15:1 selectivity between GaN and Al_{0.27}Ga_{0.73}N. While this dry etch has worked well it has several drawbacks. Primarily the etch process takes a long time. Significant run-to-run variation in the GaN etch rate has observed (FIG. 4) which requires etch rate calibrations prior to the etching of devices. Secondly the use of a fluorine-containing etch can influence the electrical properties of devices. While F-plasma treatments have been used to intentionally induce threshold voltage shifts in Ga-polar HEMTs such treatments have been shown to be unstable over time in the presence of high electric fields [7]. In Ga-polar GaN HEMTs, it has been observed that a kink appears in device output-IV characteristics when measured at cryogenic temperatures for F-treated GaN surfaces [8]. Recent measurements of N-polar deep recess HEMTs at cryogenic temperatures has also shown such a kink [9] potentially indicating residual F resulting from the selective etch.

Furthermore, the impact of F-plasma in N-polar GaN HEMT fabrication has previously been demonstrated to impact the metal-to-regrown n⁺ ohmic contact resistance. Denninghoff [10] showed that exposing the regrown n⁺ GaN surface to CF₄/O₂ plasma (as required to etch an MOCVD SiN layer) resulted in a very high contact resistance, ρ_{c}, of 2.0 Ω-mm. The contact resistance was then reduced below 0.1 Ω-mm by etching about 10 nm of the regrown n⁺ GaN layer in a BCl₃/Cl₂ RIE. This is the ‘ohmic n⁺ etch’ listed above.

With a wet etch, such as the HCl etch described in Section [A], this plasma etch can be replaced by a wet etch which allows for GaN to be etched stopping on the AlGaN cap as an etch stop layer.

This invention also makes possible the ability to dry etch part of the GaN layer and then finish off the etch with a wet etch to provide the superior surface properties.

As with the interface between the ohmic metal and regrown n⁺ GaN, the interface between the regrown GaN and the underlying GaN channel is also critical. From this perspective the removal of the AlGaN cap layer prior to the n⁺ GaN regrowth may be improved by replacing the current RIE etch process with a wet etch.

2. Structural Modifications to the Deep Recess HEMT Enabled by Wet Chemistry

(i) Asymmetric GaN Cap Recess

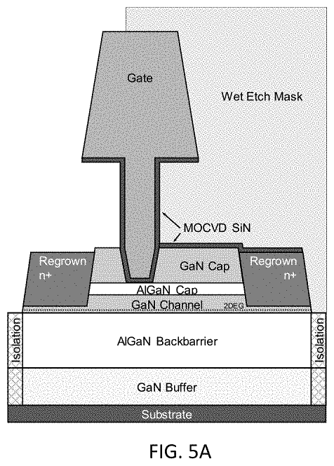

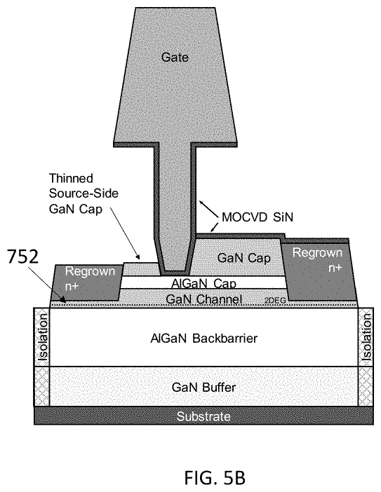

In the current N-polar GaN deep recess HEMT the fringing capacitance associated with having the foot gate metal in contact with the GaN cap recess sidewall limits performance. Through the use of wet etching, an asymmetric GaN cap recess can be obtained (FIG. 5) where the GaN cap can be thinned (partly or fully) either before or after the gate has been deposited on either the source or drain side of the device. On the source side this would be done to reduce the parasitic fringing gate-to-source capacitance (c_{gs}). On the drain side this can reduce the charge in the access region leading to the ability to obtain higher breakdown voltage [11]. The use of wet-etching greatly simplifies the formation of this structure as the T-gate head can be used to partly mask the etch leading to a reduction in alignment tolerance for the lithographic process creating that mask.

(ii) Placement of a Self-Aligned Gate with Reduced Sidewall Coverage

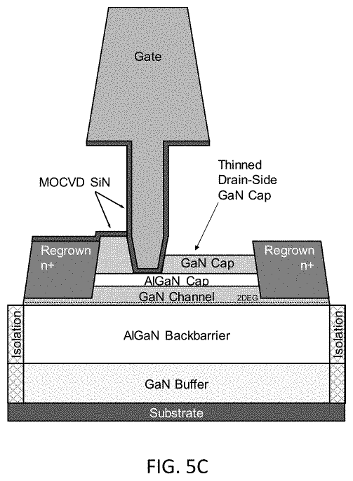

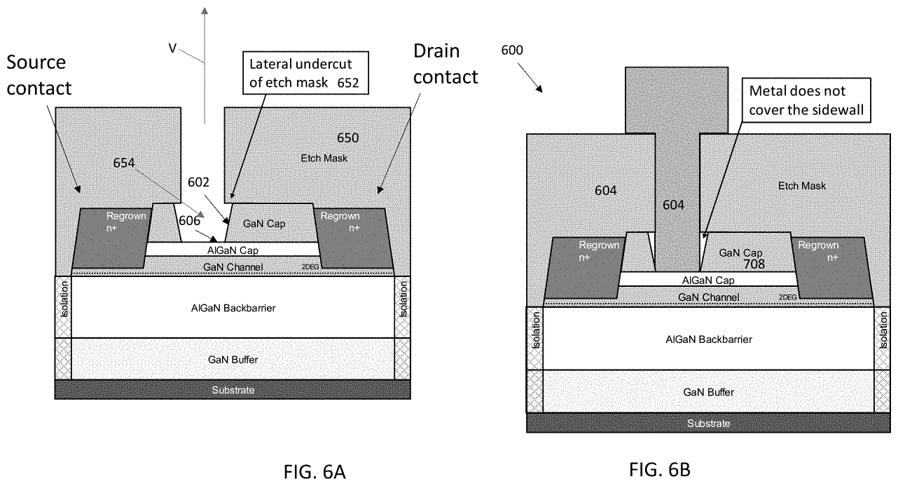

Similar to the Asymmetric GaN Cap Recess design, the use of a wet etch can allow for the formation of a gate where the gate metal covers only part or none of the GaN cap sidewall rather than the full sidewall in a self-aligned fashion. With the currently used dry etch no undercutting of the etch mask is observed as depicted in Step 5 in FIG. 3. Therefore, when the etch mask is used to define the gate-stem in a self-aligned fashion the entirety of the GaN cap is covered with gate metal. When using wet etches that have different etch rates based on direction the etched sidewall may be undercut during the wet etch as the etch is able to progress both laterally and vertically. By controlling the directional etch rates and overetch based on selectivity to the AlGaN cap layer the undercut can be controlled. As shown in FIG. 6, the lateral etch results in an undercut profile. When the same mask is used to define the gate stem as the etch and a directional gate metal deposition technique (such as e-beam or thermal evaporation) the gate stem can be deposited such that it does not contact all of the GaN cap sidewall based on the degree of undercut.

(iii) Improved Interfaces

Wet etching can be used to improve interface quality between the semiconductor surface and another material. This can include improved interfaces for the epitaxial regrowth of additional III-N material (for instance by MOCVD or MBE) or the growth or deposition of other materials such dielectrics, other semiconductors, or metals.

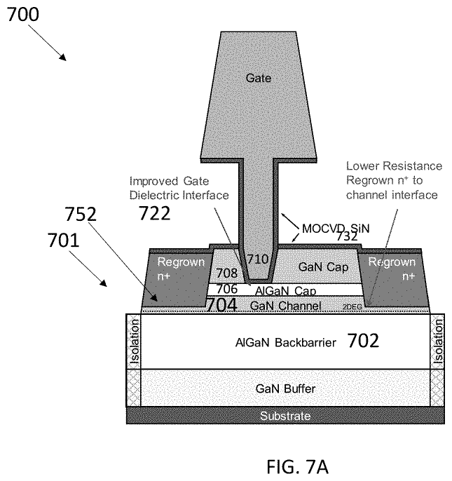

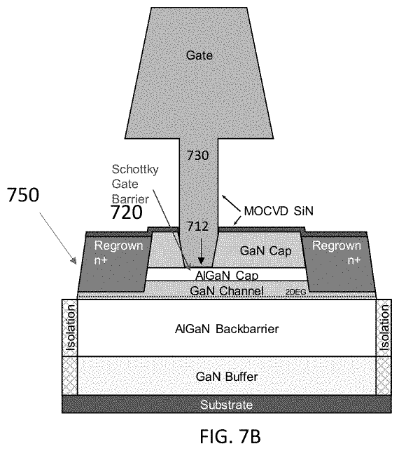

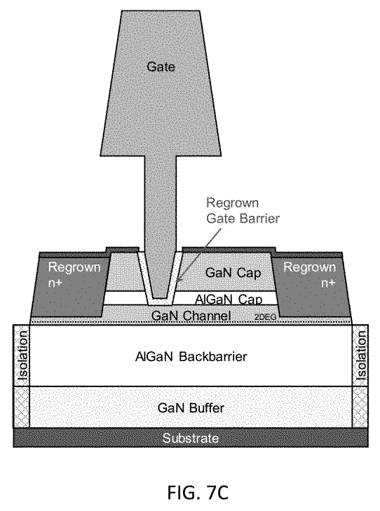

Examples of structures that can use this treatment related to improving the gate barrier are shown in FIG. 7. While shown for a deep recess HEMT structure, these processes can also be applied to planar N-polar HEMTs (a N-polar HEMT without a GaN cap).

a. Regrowth of a InxAl_{y}GazN gate barrier: Past experiments on dry etch surfaces indicated that using regrown materials on a dry-etched surface resulted in a reduction in performance. In this structure, the availability of wet etches allows for either the entire etch process to be a wet etch process or following a dry etch a wet etch can clean up that interface.

b. Improved gate dielectric interface: In the existing device, an improved interface at the AlGaN cap/SiNₓ gate dielectric interface can be obtained. The SiNₓ could also be replaced by other dielectrics.

c. Higher Schottky barrier height. It has previously been shown that the Schottky barrier height made to N-polar GaN is lower than Ga-polar GaN [12]. Through the appropriate surface treatment this barrier height can be improved.

d. Wet surface treatments may be used to increase the Schottky barrier height at a metal-semiconductor interface (such as for the formation of a gate electrode) in a manner that does not significantly degrade the physical properties (i.e. does not significantly increase the surface roughness) of the surface but modify the electrical properties providing a higher barrier.

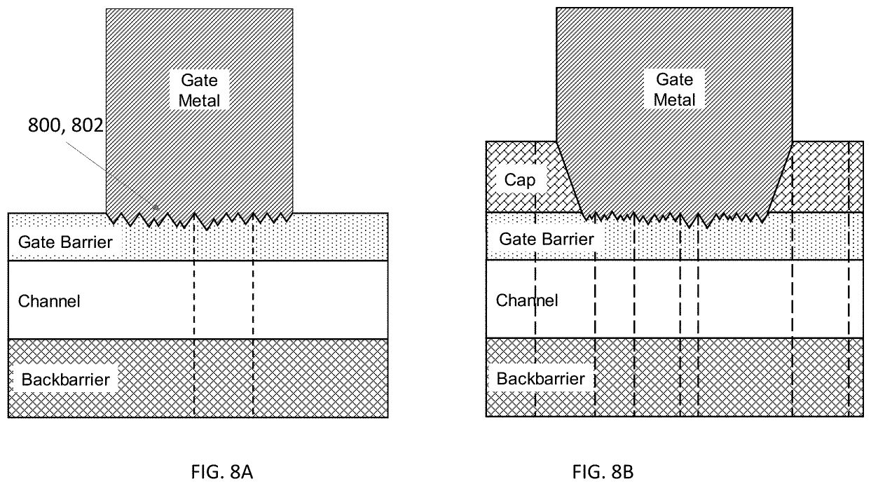

e. Alternatively, the wet etch process may increase the roughness of the surface thereby exposing crystal planes other than the N-polar plane as shown in FIG. 8 forming a composite, non-planar surface. Depositing gate metal on these composite, non-planar surfaces can increase the Schottky barrier height resulting in reduced gate leakage due to the presence of alternate crystal planes. If dislocations (indicated by the dashed lines in FIG. 3) are present in the material, this structure can also reduce leakage through the dislocation by creating a barrier around the dislocation.

f. In FIG. 8, a partial N-polar GaN transistor structure is shown where the 2 deg is formed in the Channel layer that is above the backbarrier. A Gate Barrier layer is also shown above the Channel layer. This gate barrier layer is optional and, for instance, might be an AlInGaN layer. The surface roughing of the Gate Barrier layer shown underneath the Gate Metal could extend through the Gate Barrier.

g. AlGaN caps are normally included in N-polar HEMTs to improve the gate barrier. While high Al composition would be desired for this purpose, the high Al composition can degrade the access region conductivity. Therefore, a regrown AlGaN layer with high Al composition (more generally this could be AlInGaN) only under the gate is desirable. Prior to this high composition AlGaN regrowth, a wet-etch can be used to remove the as-grown AlGaN cap allowing the regrowth to occur on the GaN channel layer. Wet etch treatments can also be used to partially etch away the GaN channel to improve the device aspect ratio or just clean up the interface without fully etching away the underlying layer.

h. Like regrown AlInGaN cap layers, regrown p-doped AlInGaN can further enhance the gate barrier which would benefit from wet-chemical surface treatments or etches prior to the epitaxial regrowth.

In other regions of the device wet-etches can also improve interfaces. This can include the n⁺ regrowth interface or the surface of the device prior to ex-situ dielectric passivation.

3. A Method to Form n-Type Contacts to N-Polar III-N's

The roughened surfaces that were observed in FIG. 1 can also be leveraged to form localized regions of n-type material at N-polar surfaces. While the method described below has been made in the context of N-polar HEMTs, this method applies to any structure where an n-type layer is formed at an N-polar surface.

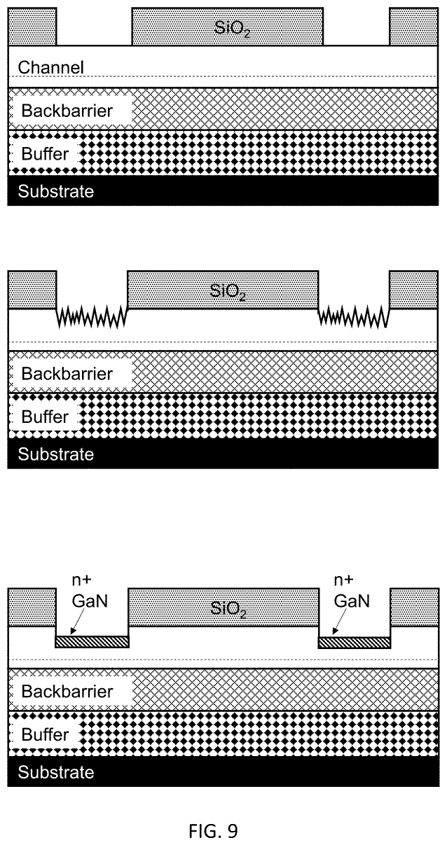

To Ga-polar GaN transistors, n-type source and drain contacts were shown to be formed using a mass-reflow technique where a trench was etched and then the sample was subjected to a high temperature anneal during which the GaN material reflowed from the etched edges while incorporating n-type dopants from the SiO₂ hard mask [13]. In this invention, rather than using a uniform, dry-etched trench where material can only reflow from the etched sidewalls, the pyramids that are the natural result of etching N-polar GaN in certain solutions is utilized to allow for the reflow to occur in a more uniform manner. The process flow for this is shown in FIG. 9 for a planar N-polar GaN HEMT and the formation of source and drain contact regions. An mask layer is first pattered exposing the N-polar surface. This mask may be a dielectric material like silicon oxide or silicon nitride but is not limited to these materials. The sample is then etched in a wet etch which results in a rough surface with pyramidal-shaped features. Upon thermal annealing those pyramidal features are allowed to reflow while incorporating dopants (for example Si, Ge, O). This anneal may be performed in any ambient that allows for the formation of n-type regions. For instance, gasses containing n-type dopant species can be used to increase the n-type conductivity. Examples of these gases include silane, disilane, germane, water vapor, nitrous oxide, etc. The n-type conductivity may come from incorporating dopants from the mask layer (for example Si or O from an SiO₂ mask) or from defects in the crystal such as N-vacancies which act as electron donors. The end result is a localized region of n-type GaN.

With the aforementioned wet-etches this localized n-type region formation can also be formed in the deep recess HEMT structure. In this case, an etchant such as HCl can be used to etch the majority of the GaN cap layer stopping on the AlGaN cap in the regions between the pyramids as HCl has been shown to have good etch selectivity of GaN over AlGaN. In the areas where the AlGaN cap surface has been exposed that layer can be etched using wet or dry etch techniques exposing the GaN channel surface below. The thermal anneal can then be performed allowing contact to the underlying channel.

C. Advantages and Improvements

Wet etching of layers that form electrical interfaces are almost always preferred over dry etches in semiconductor processing. The nature of the plasma generated for dry etch processes is known to result in both surface and subsurface damage due to the exposure to high energy charged ions and electrons. In other semiconductor systems it is well established that wet etch processes are preferred for the improvement in the device electrical characteristics that result due to the reduced interaction depth of the etchant with the sample. Additionally, devices fabricated using wet-etches have displayed reduced trapping effects, lower leakages, lower noise, and higher reliability. Furthermore, wet etches have the advantage that they often require simplified infrastructure which requires lower capital costs. Many wet etches can also be performed as batch processes and can scale between different substrate sizes more easily than dry etches further reducing manufacturing cost. To date III-N device fabrication has relied on dry etching due to the lack of wet etches available. This limitation is overcome in by this invention for the fabrication of N-polar III-N devices.

Additionally, N-polar GaN transistors have demonstrated superior RF performance, particularly at mm-wave frequencies, relative to metal-polar devices. Therefore, this invention allows for the fabrication of higher performance devices in a simplified, lower cost manner.

### REFERENCES FOR SECTION I

[1] G. C. DeSalvo, W. F. Tseng, and J. Comas, “Etch Rates and Selectivities of Citric Acid/Hydrogen Peroxide on GaAs, Al_{0.3}Ga_{0.7}As, In_{0.2}Ga_{0.8}As, In_{0.53}Ga_{0.47}As, In_{0.52}Al_{0.48}As , and InP,” Journal of The Electrochemical Society, vol. 139, no. 3, pp. 831-835, Mar. 1, 1992 1992.

[2] X. Mei et al., “First Demonstration of Amplification at 1 THz Using 25-nm InP High Electron Mobility Transistor Process,” IEEE Electron Device Letters, vol. 36, no. 4, pp. 327-329, 2015.

[3] D. Zhuang and J. H. Edgar, “Wet etching of GaN, AlN, and SiC: a review,” Materials Science and Engineering: R: Reports, vol. 48, no. 1, pp. 1-46, 1/17/2005 2005.

[4] D. Buttari, S. Heikman, S. Keller, and U. K. Mishra, “Digital etching for highly reproducible low damage gate recessing on AlGaN/GaN HEMTs,” in IEEE Lester Eastman Conference on High Performance Devices, 2002, pp. 461-469.

[5] B. Romanczyk et al., “Demonstration of constant 8 W/mm power density at 10, 30, and 94 GHz in state-of-the-art millimeter-wave N-Polar GaN MISHEMTs,” IEEE Transactions on Electron Devices, vol. 65, no. 1, pp. 45-50, 2018.

[6] S. Wienecke et al., “N-polar GaN cap MISHEMT with record power density exceeding 6.5 W/mm at 94 GHz,” IEEE Electron Device Letters, vol. 38, no. 3, pp. 359-362, 2017.

[7] C. Yi, R. Wang, W. Huang, W. C. Tang, K. M. Lau, and K. J. Chen, “Reliability of Enhancement-mode AlGaN/GaN HEMTs Fabricated by Fluorine Plasma Treatment,” in 2007 IEEE International Electron Devices Meeting, 2007, pp. 389-392.

[8] R. Cuerdo et al., “The Kink Effect at Cryogenic Temperatures in Deep Submicron AlGaN/GaN HEMTs,” IEEE Electron Device Letters, vol. 30, no. 3, pp. 209-212, 2009.

[9] B. Romanczyk et al., “Temperature-Independent Small-Signal Behavior of mm-Wave N-Polar GaN Deep Recess HEMTs,” in 2018 Lester Eastman Conference (LEC), Columbus, Ohio, USA, 2018.

[10] D. J. Denninghoff, “Highly Scaled N-polar Gallium Nitride MIS-HEMTs,” Ph.D. Dissertation, University of California, Santa Barbara, 2012.

[11] M. Guidry, S. Keller, U. K. Mishra, B. Romanczyk, and X. Zheng, “III-N Transistor Structure with Stepped Cap Layers,” Patent UC Case #2019-418, 2019

[12] B. P. Downey, D. J. Meyer, D. S. Katzer, D. F. Storm, and S. C. Binari, “Electrical characterization of Schottky contacts to N-polar GaN,” Solid-State Electronics, vol. 86, pp. 17-21, 2013/08/01/2013.

[13] S. Heikman, S. Keller, B. Moran, R. Coffie, S. P. DenBaars, and U. K. Mishra, “Mass Transport Regrowth of GaN for Ohmic Contacts to AlGaN/GaN,”physica status solidi (a), vol. 188, no. 1, pp. 355-358, 2001.

II. Device Structures Utilizing Barrier Enhancement Conductive Materials on N-Polar

Conductive materials on semiconductors have electron barriers (i.e. Schottky barrier between metal and semiconductors) that are classically described based on the energy difference between the work function of the conductive material and the electron affinity of the semiconductor. In N-polar III-nitrides systems, phenomena are known to exist which reduces this barrier height. However, a device utilizing conductive materials on N-polar III-nitrides with barrier heights greater than or equal to this difference are not known. This disclosure covers device structures where the conductive material on a N-polar group III-nitride semiconductor provides an enhanced barrier height greater than or equal to the difference between the work function and electron affinity. The barrier enhancement can be used to improve the performance of various N-polar III-nitride devices.

A. Background and Discussion

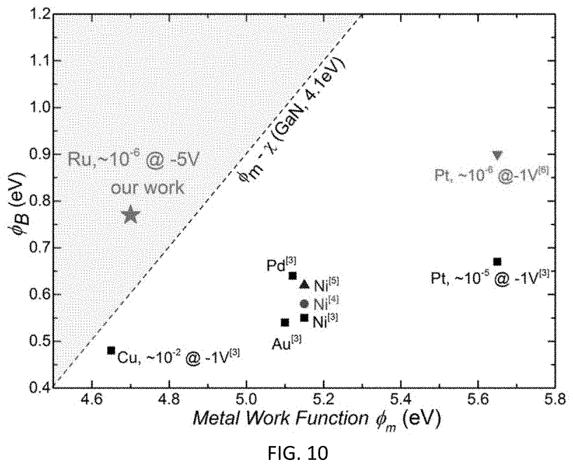

The invention arose to address a specific challenge observed with N-polar GaN utilized for detectors, sensors and amplifiers. N-polar GaN based high electron mobility transistors (HEMTs) have demonstrated superior performance for solid-state millimeter wave power amplifiers [1, 2]. To further improve the high-frequency and high-power performance in N-polar GaN HEMTs, using a small gate length while preserving a good aspect ratio is critical. Currently, N-polar HEMTs utilize a thin gate dielectric to reduce gate leakage. This reduces the aspect ratio. Therefore, removing the gate dielectrics, i.e. using conductive materials directly on N-polar GaN is very attractive to pursue highly scaled and high-performance devices. However, the barrier values (4 B) of various conductive materials on N-polar GaN studied [3-6] are limited and not larger than the difference (ϕₘ-χ) between the work function of conductive materials (pm and the electron affinity of GaN χ (below the dashed line in FIG. 10). Devices with the limited barrier values cause high leakage and impede the applications in practical diodes or transistors.

It is an object of the present invention to provide a device with barrier enhancement conductive materials on N-polar III-nitrides, which can overcome the limited barrier value (ϕₘ-χ) and reduce leakages. An embodiment of the invention covers the area above (ϕₘ-χ) dashed line without limited by the scales in the FIG. 10 and includes all N-polar III-nitrides without the limitation to N-polar GaN. As an instance, we proposed and invented Ru on N-polar GaN with (ϕ_{B}=0.77 eV) larger than (ϕₘ-χ=0.6 eV).

While there is a specific application to N-polar GaN Schottky diodes and HEMTs, the invention is more broadly applicable to other diodes and other transistors requiring the contact between conductive materials and N-polar III-nitrides.

B. Technical Description of the Device Structures

A device utilizing barrier enhancement conductive material on N-polar III-nitrides can be achieved by utilizing conductive materials on the unique surface of N-polar III-nitride materials with piezoelectric and/or spontaneous polarization. By designing the surface states and/or electric dipoles formed between conductive materials and N-polar III-nitrides, and engineering the device structures, a device with enhanced barriers (ϕ_{B}) larger than (ϕₘ-χ) can be used in many applications.

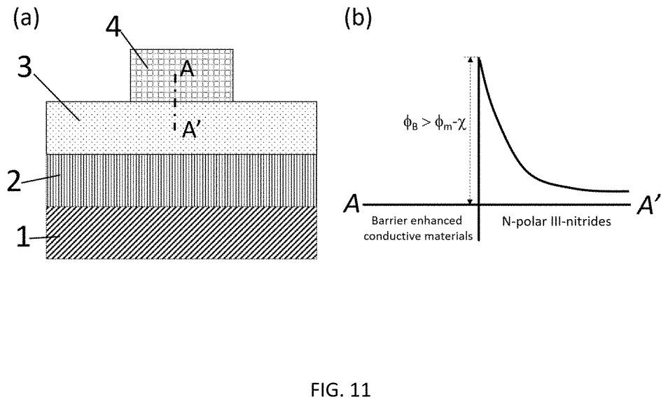

The cross-sectional structure and energy band diagram of barrier-enhanced device are shown in FIGS. 11(a) and 11(b). In FIG. 11(a), the device structure consists of the substrate 1, bottom material layer 2, N-polar III-nitride layer 3 and barrier enhanced material layer 4.

Each layer can include stacks of different materials. The barrier described in this invention occurs at the interface between 3 and 4 and therefore 3 has the property that the surface of this layer is a N-polar III-N and 4 has the property that it is a conductive material which provides the enhanced barrier. In FIG. 11(b), the band diagram of A-A′ denotes the enhanced barrier between conductive materials and N-polar III-nitrides. This structure could also be implemented in a trenched diode where the sidewall could be the high barrier material or an MOS or a p-n junction.

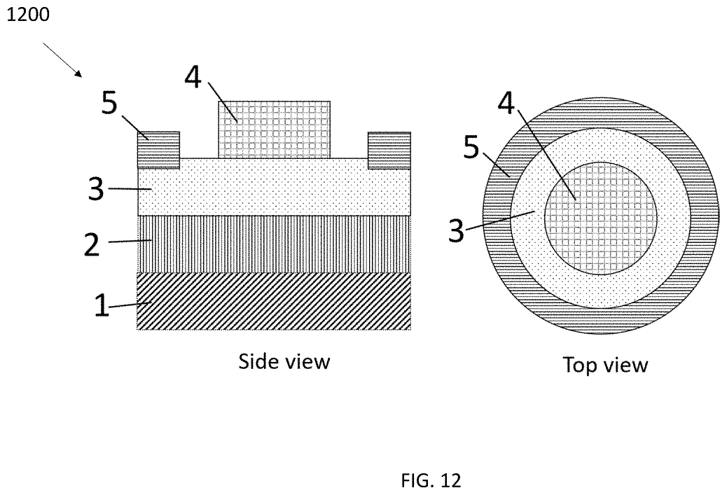

In one embodiment of the present invention, the device having barrier enhancement conductive materials on N-polar III-nitrides can be a circular diode structure (FIG. 12). The structure consists of the substrate 1, bottom material layer 2, N-polar III-nitride layer 3, barrier enhancement conductive material layer 4 and contact layer 5. Each layer can include stacks of different materials. In this embodiment of the present invention, the enhanced barrier property occurs at the interface between 3 and 4.

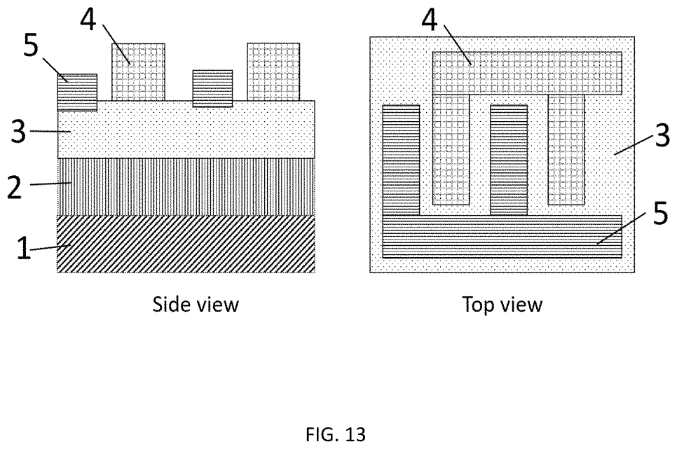

In another embodiment of the present invention, the device utilizing barrier enhancement conductive materials on N-polar III-nitrides can be an interdigitated diode structure (FIG. 13). The structure consists of the substrate 1, bottom material layer 2, N-polar III-nitride layer 3, barrier enhancement conductive material layer 4 and contact layer 5. Each layer can include stacks of different materials. In the case of this invention the enhanced barrier property occurs at the interface between 3 and 4.

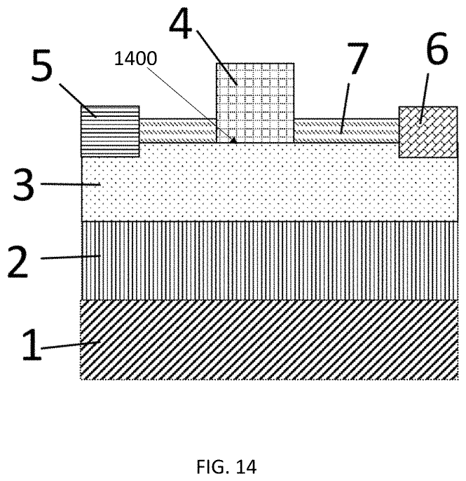

In another embodiment of the present invention, the device utilizing barrier enhancement conductive materials on N-polar III-nitrides can be a planar transistor structure (FIG. 14). The structure consists of the substrate 1, bottom material layer 2, N-polar III-nitride layer 3, barrier enhancement conductive material gate layer 4, contact source layer 5, contact drain layer 6 and passivation layer 7. Each layer can include stacks of different materials. In the case of this invention the enhanced barrier property occurs at the interface between 3 and 4. Similarly a Schottky barrier source contact or drain contact can be made wherein the barrier height property occurs at the interface between 3 and 5 (source contact) or 3 and 6.

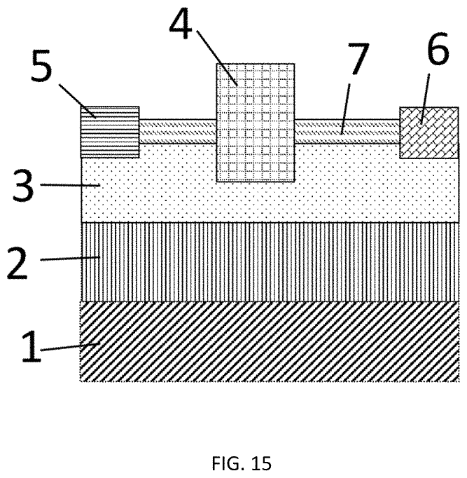

In another embodiment of the present invention, the device utilizing barrier enhancement conductive materials on N-polar III-nitrides can be a recessed transistor structure (FIG. 15). The structure consists of the substrate 1, bottom material layer 2, N-polar III-nitride layer 3, barrier enhancement conductive material gate layer 4, contact source layer 5, contact drain layer 6 and passivation layer 7. N-polar III-nitride layer 3 is recessed and barrier enhancement conductive material gate layer 4 is on top of the recessed region. Each layer can include stacks of different materials. In the case of this invention the enhanced barrier property occurs at the interface between 3 and 4. Similarly a Schottky barrier source contact or drain contact can be made wherein the barrier height property occurs at the interface between 3 and 5 (source contact) or 3 and 6.

While the four embodiment structures above are shown to implement the device utilizing barrier enhancement conductive materials on N-polar III-nitrides, the invention is more broadly applicable to other structures requiring the contact between barrier enhancement conductive materials and N-polar III-nitrides.

C. Example Demonstration

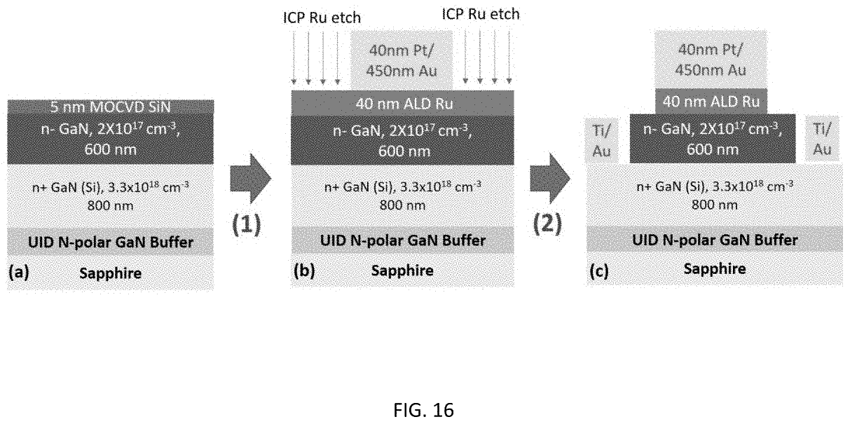

One important demonstration is that the enhanced barrier formed between the conductive materials and III-nitride shows barrier value larger than (ϕₘ-χ). In one of our prototype demonstrations, we used MOCVD epitaxy structures [7-8] and circular Schottky diode (FIG. 16(c)). Ru metal was deposited on the N-polar GaN surface by means of atomic layer deposition. The resulting measurements demonstrated 99 _{B}=0.77 eV whereas ϕₘ-χ=0.6 eV and therefore falls into the region.

For a device with enhanced barrier, the leakage in reverse bias region can be orders of magnitude less than one without enhanced barrier. For example, Cu and Ru have similar metal work function values of 4.65 eV and 4.7 eV respectively. The Cu on N-polar GaN having 0.48 eV barrier without enhancement gives ˜10⁻² A/cm² at −1V [3], and our enhanced barrier structure Ru on N-polar GaN with 0.77 eV barrier offers ˜10⁻⁶A/cm² at −5 V as shown in FIG. 7(b).

Device Fabrication: FIG. 16(a)-(16(b) shows the fabrication procedure of the Ru/N-polar GaN Schottky diode. The N-polar GaN epitaxial layers were grown on a miscut-sapphire substrate by metal organic chemical vapor deposition (MOCVD). As shown in FIG. 1(a), the epitaxial structure consisted of a UID GaN buffer layer, an 800 nm n+ GaN layer, a 600 nm n-GaN layer and a 5 nm protective SiN cap layer. In step (1), the N-polar GaN surface was exposed by the removal of the MOCVD SiN using HF: HNO3=1:1 solution and Ru was deposited on the entire sample surface by atomic layer deposition (ALD) as the Schottky contact metal. Pad metal consisting of Pt (40 nm)/Au (450 nm) is deposited using electron beam evaporation and patterned by lift-off. In FIG. 16(b), masked by the Pt/Au electrode, Cl₂/O₂ based ICP etch was used to remove the excess Ru and define the Schottky metal structure. Finally, in step (2) included mesa etching by RIE and the deposition of Ti/Au (25 nm/200 nm) ohmic contacts to n+ GaN by e-beam evaporation to give the Ru/N-polar GaN Schottky diode structure shown in FIG. 16(c).

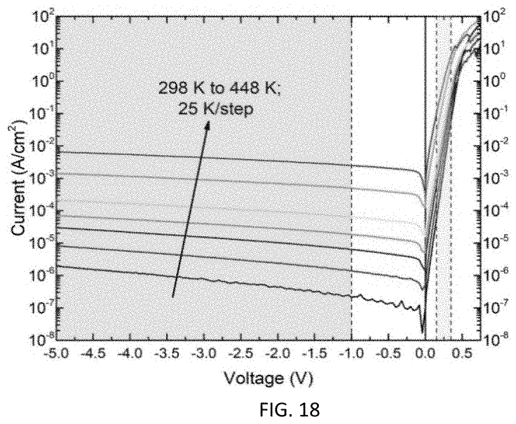

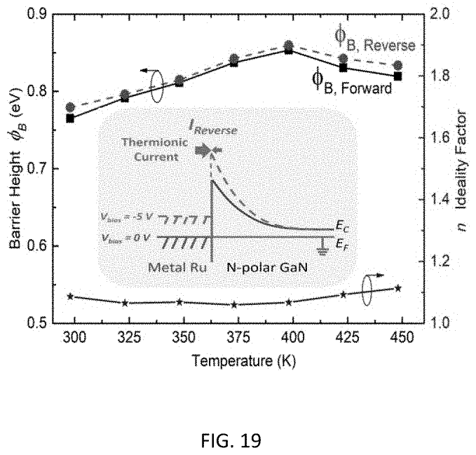

Temperature dependent DC I-V measurements from 298 K to 448 K with 25 K per step are shown in FIG. 18. Both the forward bias region and the reverse bias region were used to extract the barrier heights at different temperatures assuming a thermionic current conducting mechanism. In the forward bias region from 0.15 V to 0.3 V (>3 kT range), the barrier height ϕ_{B, Forward} and ideality factor n are extracted using ln(J)=1n(Js)+qV/nkT, 1n(Js/T²)=1n(A*)−qϕ_{B}/kT with A*=24 Acm⁻²K⁻². The extracted ϕ_{B}, Forward and n are plotted in FIG. 19 and the ˜1.1 values of n at different temperatures indicate the ideal thermionic current behavior in forward bias region. ϕ_{B} ranges from 0.77 eV at RT to 0.85 eV at 400K with the variation currently being understood. In the reverse bias region from −1 V to −5 V (<−3 kT range), the curves are linearly extrapolated to 0 V in log scale, in order to exclude the imaging charge induced barrier lowering effect and obtain the reverse saturation current value. As shown in FIG. 19, the barrier height ϕ_{B, Reverse} from reverse saturation current value fits well with ϕ_{B, Forward} at each temperature, which reveals that the current behavior in the Ru/N-polar GaN Schottky diode is thermionic in nature. The thermionic current characteristic in reverse bias region suggests that other parasitic conducting paths have been suppressed. With the combination of 0.77 eV barrier height at room temperature and a thermionic current characteristic, the reverse leakage shown in FIG. 2. is ultralow with ˜10⁻⁶ A/cm² at −5 V. Moreover, the Schottky diode has 0.77 eV barrier height value and ideal thermionic current behavior in both forward and reverse bias regions. Compared with other metals on N-polar GaN as shown in FIG. 10, the Ru/N-polar GaN Schottky diode has an exceptionally high barrier height in terms of associated metal work function value and the best electrical performance under reverse bias. Ru/N-polar GaN developed here can be applied into Schottky-HEMTs with a highly scaled gate length and can be implemented in N-polar GaN in solid state millimeter wave power amplifiers and circuits.

D. Advantages and Improvements

Embodiments of the present invention can be used to address specific challenges observed with N-polar GaN utilized for detectors, sensors and amplifiers. N-polar GaN based high electron mobility transistors (HEMTs) have demonstrated superior performance for solid-state millimeter wave power amplifiers. To further improve the high-frequency and high-power performance in N-polar GaN HEMTs, using a small gate length while preserving a good aspect ratio is critical. Currently, N-polar HEMTs utilize a thin gate dielectric to reduce gate leakage. This reduces the aspect ratio. Therefore, removing the gate dielectrics, i.e. using conductive materials directly on N-polar GaN is very attractive to pursue highly scaled and high-performance devices. However, the barrier values of various conductive materials on N-polar GaN studied are limited and not larger than the difference between the work function of conductive materials and the electron affinity of GaN. Devices with the limited barrier values cause high leakage and impede the applications in practical diodes or transistors. It is an object of the present invention to provide a device with barrier enhancement conductive materials on N-polar III-nitrides, which can overcome the limited barrier value and reduce leakage.

While there is a specific application to N-polar GaN Schottky diodes and HEMTs, the invention is more broadly applicable to other diodes and other transistors requiring the contact between conductive materials and N-polar III-nitrides.

### REFERENCES FOR SECTION II

[1] S. Wienecke, et al., “N-polar GaN cap MISHEMT with record power density exceeding 6.5 W/mm at 94 GHz”, IEEE Electron Device Lett., vol. 38, no. 3, pp. 359-362, 2017.

[2] B. Romanczyk, et al., “Demonstration of constant 8 W/mm power density at 10, 30, and 94 GHz in state-of-the-art millimeter-wave N-polar GaN MISHEMTs,” IEEE Trans. Electron Devices, vol. 65, no. 1, pp. 45-50, 2018.

[3] B. P. Downey, et al. “Electrical characterization of Schottky contacts to N-polar GaN,” Solid State Elec., vol. 86, p17-21, 2013.

[4] T. Suemitsu, et al. “Effective Schottky barrier height model for N-polar and Ga-polar GaN by polarization-induced surface charges with finite thickness,” Phys. Status. Solidi B 2020, 1900528, 2019.

[5] Y. Liu, et al., “Effects of hydrostatic and uniaxial stress on the Schottky barrier heights of Ga-polarity and N-polarity n-GaN,” Appl. Phys. Lett., vol. 84, pp. 2112-2114, 2004.

[6] U. Karrer, et al., “Influence of crystal polarity on the properties of Pt/GaN Schottky diodes,” Appl. Phys. Lett., vol. 77, pp. 2012-2014, 2000.

[7] I. Sayed, et al., “Net negative fixed interface charge for Si₃N₄ and SiO₂ grown in situ on 000-1 N-polar GaN,” Appl. Phys. Lett., vol. 115, 032103, 2019.

[8] W. Liu, et al., “An improved methodology for extracting interface state density at Si₃N₄/GaN,” Appl. Phys. Lett., vol. 116, 022104, 2020.

Nomenclature

The terms “III-nitride” as used herein (as well as the terms “Group-III nitride”, or “III-N”, or “nitride,” used generally) refer to any alloy composition of the (Sc,Ga,Al,In,B)N semiconductors having the formula ScᵥGa_{w}AlₓIn_{y}B_{z}N where 0≤v≤1, 0≤w≤1, 0≤x≤1, 0≤y≤1, 0≤z≤1, and v+w+x+y+z=1. These terms are intended to be broadly construed to include respective nitrides of the single species, Sc, Ga, Al, In and B, as well as binary, ternary, quaternary and pentanary compositions of such Group III metal species. Accordingly, it will be appreciated that the discussion of the invention hereinafter in reference to GaN materials is applicable to the formation of various other (Sc,Ga,Al,In,B)N material species. Furthermore, (Sc,Ga,Al,In,B)N materials within the scope of the invention may include minor quantities of dopants and/or other impurity or inclusional materials. The term “non-III-nitride” or “non-III-N” refers to any semiconductor that is excluded from the definition provided for the term “III-nitride” or “III-N.”

The term “N-polar” refers to the (000-1) plane of III-nitride materials.

Device and Method Embodiments

Process Steps

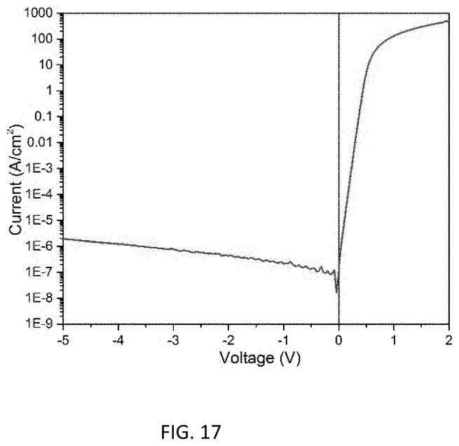

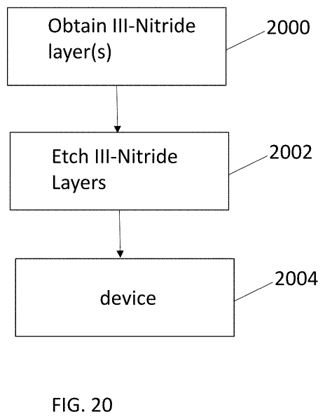

FIG. 20 illustrates is a flowchart illustrating a method of making a device (referring also to labels in FIGS. 1-19).

Block 2000 represents obtaining one or more N-polar III-Nitride layers 701.

Block 2002 represents etching one or more of the N-polar III-Nitride layer 701, wherein the etching comprises wet etching using one or more wet etchants.

Block 2004 represents the end result, a device or layer useful in a device 700 (as illustrated e.g., FIGS. 2, 5A-5C, 6A-6B,7A-7C, 8, and 9). Although 5A-5C, 6A-6B,7A-7C show specific compositions for channel, barrier layers, cap layers, these layers can have different (e.g., III-Nitride) compositions as described herein.

Illustrative, non-exclusive examples of inventive subject matter according to the present disclosure are described in the following enumerated paragraphs (referring also to the figures):

1. A method of making a device (e.g., as illustrated in FIG. 2), comprising:

obtaining an III-N layer (e.g., N-polar GaN layer) having a surface, wherein the surface has a starting surface roughness; and

etching the surface, wherein the etching comprises wet etching using a wet etchant (e.g., having a composition) such that a final surface roughness of the surface (e.g., 200), formed by the wet etching, is not increased by more than a factor of 3 as compared to the starting surface roughness. In one or more examples, the final surface roughness remains below 3.0 nanometers root mean square (rms) roughness, regardless of the starting surface roughness. In one or more examples, the surface roughness of less than 3.0 nm is over a surface area of 2 micrometers by 2 micrometers or less. In one or more examples, the final surface roughness is at least 0.1 nm rms, e.g., over the surface area of 2 microns by 2 microns.

2. The method of clause 1, wherein the etching comprises at least one of:

(a) the wet etching using the wet etchant comprising aqueous citric acid (and optionally also an additional component such as H₂O₂) at a temperature above room temperature (e.g., above 40 degrees Celsius). In one or more examples the aqueous citric acid comprises a 1.0 molar (M) or 5.3M citric acid solution. However, the aqueous citric acid solution can have a variety of concentrations of citric acid. In one or more examples, the aqueous citric acid comprises an at least 0.05M citric acid solution.

(b) etching using sequential cycles of O₂ plasma treatment and the wet etching using the wet etchant comprising citric acid, e.g., at room temperature; In one or more examples, the temperature is up to 80 Celsius. In one or more examples, the citric acid is diluted with H₂O and the temperature is increased to get to the same etch rate.

(c) the wet etchant comprising ammonium sulfide;

(d) the wet etchant comprising a mixture of phosphoric acid, nitric acid, acetic acid, and water;

(e) the wet etchant comprising an aqueous mixture of HCl (and optionally an additional component, e.g., HNO₃); or

(f) the wet etchant comprising an aqueous mixture of HBr (and optionally an additional component, e.g., HNO₃).

3. A method of making an N-polar III-N device , comprising at least one of:

performing a wet etch that etches one or more N-polar III-N layers, wherein the wet etch uses a solution comprising a first etchant having a composition that etches (e.g., N-polar) AlₓGa₁₋ₓN faster than (e.g., N-polar) Al_{y}Ga_{1-y}N where x is less than y (e.g., preferentially etches N-polar GaN over N-polar AlGaN), or

performing a wet etch that etches one or more N-polar III-N layers, wherein the wet etch uses a solution comprising a second etchant having a composition that etches (e.g., N-polar) AlₓGa₁₋ₓN faster than (e.g., N-polar) Al_{y}Ga_{1-y}N where x is greater than y (e.g., preferentially etches N-polar AlGaN over N-polar GaN), or

digitally etching one or more of the N-polar III-N layers using a dry oxidation step exposing the one or more layers to an oxidizer so as to form an oxidized surface layer; and then wet etching the oxidized surface layer using an etchant that etches the oxidized surface layer at least 10 times faster than the underlaying layer.

4. The method of any of the clauses 1-2 in combination with the method of clause 3.

5. A method of making a device, comprising:

obtaining III-Nitride N-polar layers comprising a nitride barrier layer comprising aluminum (e.g., AlGaN, InAlN), a (e.g., GaN) channel layer on or above the nitride barrier layer; a nitride cap layer comprising aluminum on or above the (e.g., GaN) channel layer; and a (e.g., GaN) cap layer 708 on or above the nitride cap layer; and

etching one or more of the layers, comprising wet etching using one or more solutions comprising at least one of:

the first etchant having a composition that etches AlₓGa₁₋ₓN faster than (e.g., N-polar) Al_{y}Ga_{1-y}N where x is less than y (e.g., preferentially etches N-polar GaN over N-polar AlGaN), or

the second etchant having a composition that etches (e.g., N-polar) AlₓGa₁₋ₓN faster than (e.g., N-polar) Al_{y}Ga_{1-y}N where x is greater than y (e.g., preferentially etches N-polar AlGaN over N-polar GaN).

6. The method of any of the clauses 1-4 in combination with the method of clause 5.

7. The method of any of the clauses 3-6, wherein the solution comprising the first etchant includes a mixture containing an inorganic acid as an active ingredient.

8. The method of clause 7, wherein the mixture comprises an aqueous mixture of at least one of HCl or HBr.

9. The method of any of the clauses 3-6, wherein the solution comprising the second etchant includes a mixture containing an organic acid as an active ingredient.

10. The method of clause 10, wherein the mixture comprises an aqueous mixture of at least one of citric acid or phosphoric acid.

11. The method of any of the clauses 3-10, further comprising adding an additional component comprising at least one of HNO₃ or H₂O₂ to the solutions to tune an etch property of the wet etching.

12. The method of any of the clauses 3-11, wherein the layers comprise a doping profile that increases the preferential etching.

13. The method of any of the clauses 1-12, wherein the etching further comprises:

digitally etching one or more of the layers using a dry oxidation step exposing the one or more layers to an oxidizer so as to form an oxidized surface layer; and

performing the wet etching using the one or more solutions that etch the oxidized surface layer at least 10 times, or at least 100 times faster than the underlaying layer.

14. A device 700 manufactured using the method of any of the clauses 1-13, e.g., as illustrated in FIGS. 5A-5B, 6A-6C, 7A-7C, 8, or 9.

15. The method of any of the clause 1-14, wherein:

the device comprises a high electron mobility transistor, and

the wet etching etches at least one of:
a recess through part of the (e.g., GaN) cap layer that does not expose the nitride cap layer;

a recess 710 through the (e.g., GaN) cap layer that exposes the nitride cap layer 706,
a thickness 750 through the (e.g., GaN) cap layer and the nitride cap layer so as to expose 752 the (e.g., GaN) channel layer 704, or
a recess 750 through part of one or more of the III-Nitride layers 701.

16. FIG. 6A and 6B illustrate the method of any of the clauses 1-15, wherein:

the device comprises a high electron mobility transistor, and

the method further comprises depositing an etch mask 650 on the (e.g., GaN) cap layer 708,

the wet etching etches the recess 654 comprising a gate recess through the (e.g., GaN) cap layer 708, forming a lateral undercut 652 in the etch mask, and

the method further comprises depositing gate metal 604 in the gate recess, wherein the lateral undercut 652 allows deposition of the gate metal in a self-aligned manner and reduces or eliminates deposition of the gate metal on sidewalls 602 of the (e.g., GaN) cap layer 708.

17. The method of clause 16, wherein the gate metal is deposited from a vertical direction and/or the sidewalls 602 are inclined so that the gate recess is wider with increasing distance in a vertical direction V from and perpendicular to the wet etched surface 606 of the nitride cap layer, and less of the gate metal is on the sidewalls 602 with the increasing distance from the wet etched surface.

18. The method of any of the clauses 1-17, wherein:

the wet etching exposes at least one of an N-polar wet etched surface of the (e.g., GaN) channel or a wet etched surface of the nitride cap layer;

the method further comprises forming a metal-semiconductor junction or metal-insulator-semiconductor junction on the N-polar wet etched surface, wherein the metal-semiconductor junction has at least one of an increased barrier height or a reduced junction leakage obtained by the wet etching roughening the N-polar wet etched surface.

19. The method of clause 18, wherein the roughening reduces a leakage of charge through dislocations.

20. The method of any of the clauses 1-19, wherein the wet etching forms the recess exposing at least one of a wet etched surface of the (e.g., GaN) cap layer or a wet etched surface of the nitride cap layer or a wet etched surface of the (e.g., GaN) channel layer, the method further comprising:

depositing gate metal on the wet etched surface so as to form an electrical interface with the wet etched surface, the electrical interface comprising a Schottky barrier, and the electrical interface comprising at least one of a higher Schottky barrier height (e.g., by at least 0.1 eV (eV=electron volts)) or a reduced gate leakage (by a factor of 10 or more) relative to a dry-etched or non-wet-etch treated surface (e.g., of the nitride cap layer, GaN cap layer, or GaN channel layer) and with an absolute gate leakage below 1 milliamp/millimeter at a drain voltage at or below 0.5 V (e.g., in a range 0-0.5 V) and a gate voltage corresponding to 1 milliamp/millimeter of drain current.

21. The method of any of the clauses 1-18, wherein the wet etching forms the recess (e.g., comprising a gate recess) and exposes an N-polar wet etched surface of the N-polar III-Nitride layer (e.g., nitride cap layer, GaN cap layer, or GaN channel layer), the method further comprising:

depositing a dielectric layer in the recess and on the N-polar III-Nitride layer (e.g., nitride cap layer, GaN cap layer, or GaN channel layer), wherein an electrical N-polar-dielectric interface, between the dielectric layer and the N-polar wet etched surface, has a reduced number of interface states as compared when the interface is formed using dry etching.

22. The method of any of the clauses 1-21, further comprising:

wet etching an N-polar surface of one or more of the layers so as to form a roughened N-polar surface; and

thermally annealing the roughened N-polar surface in an environment wherein the roughened N-polar surface reflows and becomes an n-type layer (e.g., n-type contact layer).

23. The method of clause 22, wherein the n-type layer is formed across the entire N-polar surface or in a selective area manner by masking part of the N-polar surface so that the un-masked region is n-type.

24. The method of clause 22 or 23, further comprising controlling the n-type layer's conductivity by at least one of:

adjusting an ambient of the environment during the thermal annealing in which the thermal anneal is performed, or

providing a dopant species adjacent the N-polar roughened surface prior to, or during, the thermal annealing.

25. The method of any of the clauses 1-24, wherein the device comprises the nitride barrier layer confining a two dimensional electron gas (2DEG) or two dimensional hole gas (2DHG) in the GaN channel layer comprising GaN.

26. The method of any of the clauses 1-25, further comprising a source contact (metal) and a drain contact (metal) to the GaN channel layer formed on the wet etched surfaces of the GaN channel layer exposed by the wet etching.

27. The method of any of the clauses 14-26, wherein a voltage difference applied to the gate metal with respect to the source contact or the drain contact controls a flow of current through the GaN channel, 2DEG, or 2DHG between the source contact and the drain contact.

28. The method of any of the clauses 1-27 comprising a gate in physical contact with a nitride cap layer, wherein the gate comprises a conductive material enhancing a barrier height with respect to the nitride cap layer, e.g., so as to form a barrier height of at least 0.5 eV with respect to the nitride cap layer (e.g., wherein the barrier height comprises a conduction band difference between the nitride cap layer and the conductive material at/near the interface between conductive material and the nitride cap layer).

29. The method of any of the clauses comprising a gate metal contacting a nitride cap layer, wherein the gate metal comprises ruthenium metal or an alloy comprising greater than 20% ruthenium metal and the gate metal forms a barrier height greater than 0.6 eV with respect to the nitride cap layer (e.g., wherein the barrier height comprises a conduction band difference between the nitride cap layer and the gate metal at/near the interface between conductive material and the nitride cap layer).

30. The method of any of the clauses 1-29 comprising a nitride cap layer, wherein the wet etching forms a recess comprising a gate recess and exposes an N-polar wet etched surface of the nitride cap layer, the method further comprising:

depositing a dielectric layer in the recess and on the nitride cap layer, wherein an electrical N-polar-dielectric interface, between the dielectric layer and the N-polar wet etched surface, has a reduced number of interface states by a factor of 2 or more as compared when the interface is formed using dry etching and with an overall density of interface states below 5×10¹² cm⁻²eV¹.

31. The method of any of the clauses 1-30 including a nitride cap layer and a gate recess, wherein the wet etching etches a thickness of the nitride (e.g., GaN) cap layer so that the nitride cap layer is thinner on one side of the gate recess than the other.

32. The method clause 31, comprising a T-shaped gate metal in the recess and wherein the T-shaped gate metal is used as a mask during the wet etching.

33. A device manufactured using the method of any of the clauses 1-32.

34. An N-polar III-N device 700, comprising (see e.g. FIG. 7A, 7B):

N-polar layers 701 comprising a nitride (e.g., III-Nitride) barrier layer 702 comprising aluminum and gallium, a nitride (e.g., GaN) channel 704 on or above the nitride barrier layer; a nitride cap layer 706 comprising aluminum on or above the nitride (e.g., GaN) channel layer; and a nitride (e.g., GaN) cap layer 708 on or above the nitride cap layer; and at least one of:

a gate recess 710 wet etched through the nitride (e.g., GaN) cap layer that exposes an N-polar wet etched surface 712 of the nitride cap layer using a first solution comprising a first etchant that having a composition that etches (e.g., N-polar) AlₓGa₁₋ₓN faster than (e.g., N-polar) Al_{y}Ga_{1-y}N where x is less than y (e.g., preferentially etches N-polar GaN over N-polar AlGaN), or

one or more thicknesses or openings wet etched through the nitride (e.g., GaN) cap layer and the nitride cap layer so as to expose an N-polar wet etched surface 716 of the nitride (e.g., GaN) channel layer using a second solution comprising a second etchant that that etches (e.g., N-polar) AlₓGa₁₋ₓN faster than (e.g., N-polar) Al_{y}Ga_{1-y}N where x is greater than y (e.g., preferentially etches N-polar AlGaN over N-polar GaN),.

35. The device of clause 34, wherein:

the device comprises a high electron mobility transistor 600 (e.g. FIG. 6B),

the gate recess 710 comprises inclined wet etched sidewalls 602 of the GaN cap layer formed by an anisotropic etch profile of the wet etching using the first solution, and

gate metal 604 in the gate recess and on or above the N-polar wet etched surface 606 of the nitride cap layer but not on the wet etched sidewalls 602, or wherein there is less of the gate metal on the wet etched sidewalls as compared to gate metal deposited into a gate recess having vertical sidewalls.

36. The device of clause 35, wherein the sidewalls are inclined so that the gate recess is wider with increasing distance in a vertical direction from and perpendicular to the wet etched surface 606 of the nitride cap layer, and less of the gate metal is on the sidewalls with the increasing distance from the wet etched surface.

37. The device of any of the clauses 34-36 (FIG. 7A, 7B), further comprising:

a metal-semiconductor junction 720 or metal-insulator-semiconductor junction 722 on at least one of the N-polar wet etched surface 712 of the nitride cap layer or N-polar wet etched surface of the GaN channel layer, wherein the metal-semiconductor junction has at least one of an increased barrier height or a reduced junction leakage obtained by the wet etching roughening the N-polar wet etched surface.

38. The device of any of the clauses 34-37 (FIG. 7B), further comprising:

gate metal 730 in the gate recess 710 forming an electrical interface 720 with the N-polar wet etched surface 712 of the nitride cap layer, the electrical interface comprising a Schottky barrier, and the electrical interface comprising at least one of a higher Schottky barrier height or a reduced gate leakage relative to a dry-etched or non-wet-etch treated surface of the nitride cap layer.

39. The device of any of the clauses 34-37 (FIG. 7B), comprising:

gate metal 730 in the gate recess 710 forming an electrical interface with the N-polar wet etched surface 712, the electrical interface comprising a Schottky barrier, the electrical interface comprising at least one of a higher Schottky barrier height by 0.1 eV or more or a reduced gate leakage by a factor of 10 or more relative to a dry-etched or non-wet-etch treated surface and such that the gate metal 730 forms a gate with an absolute gate leakage below 1 mA/mm at a drain voltage at or below 0.5 V and a gate voltage corresponding to 1 milliamp/millimeter of drain current .

40. The device of any of the clauses 34-39 (FIG. 7A), further comprising a dielectric layer 732 in the gate recess 710 forming an electrical N-polar-dielectric interface 722 with the N-polar wet etched surface 712 of the nitride cap layer 706, wherein the N-polar-dielectric interface 722 has a reduced number of interface states as compared when the N-polar interface with the dielectric layer is formed using dry etching.

41. The device of any of the clauses 34-40 (FIG. 9), further comprising:

the N-polar wet etched surface of the GaN channel layer having an n-type conductivity characterized by roughening by the wet etching and thermally annealing in an environment wherein the roughened N-polar surface reflows and becomes an n-type layer (n+ GaN in FIG. 9).

43. The device of any of the clauses 34-41, wherein the wet etching etches a thickness of the nitride (e.g., GaN) cap layer so that the nitride (e.g., GaN) cap layer is thinner on one side of the gate recess than the other (see FIG. 5A and 5B).

44. The device of clause 43, comprising a T-shaped gate metal in the recess and wherein the T-shaped gate metal is used as a mask during the wet etching (see e.g., FIG. 5A)

45. The method or device of any of the clauses 1-44, comprising:

a conductive material 730, 3 on or above the wet etched surface 712 of the nitride semiconductor 4 (e.g., nitride cap layer 706) and forming an interface 722 between the conductive material and the N-polar group III-nitride semiconductor of the nitride cap layer, wherein:

a barrier height ϕ_{B} comprising a conduction band difference between the N-polar III-nitride semiconductor 4 and the conductive material 3 at/near the interface is larger than the difference between the work function of the conductive material and the electron affinity of the N-polar group III-Nitride semiconductor, wherein the conductive material forms a Schottky barrier between the semiconductor and the conductive material.

46. The device of clause 45, wherein the conductive material comprises ruthenium metal.

47. The device of any of the clauses 34-46, comprising a gate 730 in the gate recess 710 in in physical contact with a nitride cap layer 706, wherein the gate comprises a conductive material 3 enhancing a barrier height ϕ_{B} with respect to the nitride cap layer 706, e.g., so as to form a barrier height ϕ_{B} of at least 0.5 eV with respect to the nitride cap layer (e.g., wherein the barrier height comprises a conduction band difference between the nitride cap layer and the conductive material at/near the interface between conductive material and the nitride cap layer).

48. The device of any of the clauses 34-46 or the method of any of the clauses 1-47 comprising a gate metal 730 in the gate recess 710 contacting the nitride cap layer 706, wherein the gate metal comprises ruthenium metal or an alloy comprising greater than 20%, greater than 30%, greater than 50%, or greater than 80% ruthenium metal, or consisting essentially of ruthenium metal, and the gate metal forms a barrier height greater than 0.6 eV with respect to the nitride cap layer (e.g., wherein the barrier height comprises a conduction band difference between the nitride cap layer and the gate metal at/near the interface between conductive material and the nitride cap layer).

49. The device of clause 34, wherein the N-polar semiconductor comprises a III-Nitride layer (e.g., gallium nitride) and the barrier height is greater than or equal to 0.5 eV (or e.g., greater than 0.6 eV when the conductive material is ruthenium metal).

50. The method or device of any of the clauses 1-49, wherein the wet etching etches a thickness of the GaN cap layer so that the GaN cap layer is thinner on one side of the gate recess than the other (see FIG. 5A-5C).

51. The method or device of clause 50, comprising a T-shaped gate metal in the recess and wherein the T-shaped gate metal is used as a mask during the wet etching (see FIG. 5A).

52. The device of any of the clauses 33-51, wherein the nitride barrier layer confines a two dimensional electron gas (2DEG) or two dimensional hole gas (2DHG) in the GaN channel layer comprising GaN.

53. The device of any of the clauses 33-52, further comprising a source contact (metal) and a drain contact (metal) to the GaN channel layer formed on the wet etched surfaces of the GaN channel layer exposed by the wet etching.

54. The device of any of the clauses 33-53, wherein a voltage difference applied to the gate metal with respect to the source contact or the drain contact controls a flow of current through the GaN channel, 2DEG, or 2DHG between the source contact and the drain contact.

55. The method or device of any of the clauses 1-55, wherein the nitride barrier layer comprises AlGaN, the nitride cap layer comprises AlGaN, and the GaN cap layer consists essentially of GaN.

56. A device, comprising:

an III-N layer (e.g., N-polar GaN layer) having a wet etched surface 200 (see FIG. 2) wet etched using a wet etchant (e.g., having a composition) such that a final surface roughness of the surface, formed by the wet etching, is not increased by more than a factor of 3 as compared to the starting surface roughness. In one or more examples, the final surface roughness remains below 3.0 nanometers root mean square (rms) roughness, regardless of the starting surface roughness.

57. A device (see FIG. 5A-5C, 6A-6B, 7A-7B, 8, and 9), comprising a wet etched

surface formed by at least one of:

a wet etch that etches one or more N-polar III-N layers 701, wherein the wet etch uses a solution comprising a first etchant having a composition that etches (e.g., N-polar) AlₓGa₁₋ₓN faster than (e.g., N-polar) Al_{y}Ga_{1-y}N where x is less than y (e.g., preferentially etches N-polar GaN over N-polar AlGaN), or

a wet etch that etches one or more N-polar III-N layers 701, wherein the wet etch uses a solution comprising a second etchant having a composition that etches (e.g., N-polar) AlₓGa₁₋ₓN faster than (e.g., N-polar) Al_{y}Ga_{1-y}N where x is greater than y (e.g., preferentially etches N-polar AlGaN over N-polar GaN), or

digitally etching one or more of the N-polar III_N layers 701 using a dry oxidation step exposing the one or more layers to an oxidizer so as to form an oxidized surface layer; and then wet etching the oxidized surface layer using an etchant that etches the oxidized surface layer at least 10 times faster than the underlaying layer.

58. The device of clause 56 or 57, wherein the wet etched surface 606, 712 (formed by the wet etch) forms an electrical contact with a gate, a source, a drain, or any electrical contact supplying current to, receiving current from, applying voltage to, or sensing voltage outputted from, the device. Example devices include, but are not limited to, a transistor, a solar cell, a photodiode, or a light emitting device (e.g., laser or light emitting diode).

59. A device of any of the clauses comprising any of the clauses 45-54

60. A diode or transistor device 1200 (see FIG. 11-16), comprising:

an N-polar group III-nitride semiconductor 4; and

a conductive material 3 on or above the semiconductor 4 and forming an interface 1400 between the conductive material and the N-polar group III-nitride semiconductor, wherein:

a barrier height ϕ_{B} comprising a conduction band difference between the N-polar III-nitride semiconductor 4 and the conductive material 3 at/near the interface 1400 is larger than the difference between the work function ϕₘ the conductive material and the electron affinity X of the N-polar group III-Nitride semiconductor 4, wherein the conductive material 3 forms a Schottky barrier between the semiconductor 4 and the conductive material 3.

61. The device of clause 60, wherein the conductive material 3 comprises ruthenium metal or an alloy containing greater than 20%, greater than 50%, or greater than 80% ruthenium metal, or the conductive material consists essentially of ruthenium metal, and the conductive material forms a barrier height ϕ_{B} greater than 0.6 eV to the N-polar III-nitride semiconductor.

62. The device of clause 60 or 61, wherein the conductive material comprises ruthenium metal.

63. The device of any of the clauses 60-62, wherein the N-polar semiconductor 4 is a III-Nitride (e.g., gallium nitride) and the barrier height is greater than or equal to 0.5 eV.

64. The device of clause 59, wherein the conductive material 3 comprises any conductive material, including various metals, conductive oxide, conductive nitrides or conductive polymers forming the enhanced barrier height on N-polar III-Nitrides.

65. The device of any of the clauses 60 or 64, wherein the conductive material comprises any element or alloy with a work function >4.1 eV.

66. The device of any of the preceding clauses 60-65, wherein the conductive material forms a Schottky barrier between the semiconductor and the conductive material.

67. The device of any of the clauses 60-66, wherein the device comprises a diode (e.g., Schottky diode), e.g., comprising a Schottky junction between the conductive material and the N-polar group III-Nitride semiconductor comprising an n-type or p-type material.

68. The device of any of the clauses 60-67, wherein the device comprises a transistor.

69. The device of clause 68, wherein the conductive layer confines a two dimensional electron gas (2DEG) or two dimensional hole gas (2DHG) in the N-polar III-Nitride semiconductor (e.g., GaN channel layer comprising GaN).

70. The device of clause 68 or 69, further comprising a source contact (metal) and a drain contact (metal) to N-polar III-Nitride semiconductor.

71. The device of clause 70, wherein a voltage difference applied to the conductive layer with respect to the source contact or the drain contact controls a flow of current through the GaN channel, 2DEG, or 2DHG between the source contact and the drain contact.

72. The method or device of any of the clauses, wherein the conductive material is deposited using methods include but not limited to atomic layer deposition, sputtering, thermal evaporation such that the final conductive materials on N-polar III-Nitrides can form an enhanced barrier height.

Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of making a device, comprising:
obtaining an N-polar III-N layer having a surface, wherein the surface has a starting surface roughness; and
etching the surface, wherein the etching comprises wet etching using a wet etchant such that a final surface roughness of the surface, formed by the wet etching, is not increased by more than a factor of 3 as compared to the starting surface roughness, and the final surface roughness is below 3.0 nm rms roughness.

2. The method of claim 1, wherein the etching comprises at least one of:
(d) the wet etching using the wet etchant comprising aqueous citric acid at a temperature above room temperature;
(e) etching using sequential cycles of O₂ plasma treatment and the wet etching using the wet etchant comprising citric acid ;
(f) the wet etchant comprising ammonium sulfide;
(d) the wet etchant comprising a mixture of phosphoric acid, nitric acid, acetic acid, and water;
(e) the wet etchant comprising an aqueous mixture of HCl; or
(f) the wet etchant comprising an aqueous mixture of HBr.

3. The method of claim 2, wherein:
the wet etchant comprising aqueous citric acid further comprises H₂O₂, or
the wet etchant comprising HCL further comprises HNO₃, or
the wet etchant comprising HBr further comprises HNO₃

4. A method of making an N-polar III-N device, comprising at least one of:
performing a wet etch that etches one or more N-polar III-N layers, wherein the wet etch uses a solution comprising a first etchant that etches AlₓGa₁₋ₓN faster than Al_{y}Ga_{1-y}N where x is less than y,
performing a wet etch that etches one or more N-polar III-N layers, wherein the wet etch uses a solution comprising a second etchant that etches AlₓGa₁₋ₓN faster than Al_{y}Ga_{1-y}N where x is greater than y , or
digitally etching one or more of the N-polar III-N layers using a dry oxidation step exposing the one or more layers to an oxidizer so as to form an oxidized surface layer; and then wet etching the oxidized surface layer using an etchant that etches the oxidized surface layer at least 10 times faster than the underlaying layer.

5. The method of claim 4, wherein the solution comprising the first etchant includes a mixture containing an inorganic acid as an active ingredient.

6. The method of claim 5, wherein the mixture comprises an aqueous mixture of at least one of HCl or HBr.

7. The method of claim 4, further comprising adding an additional component comprising at least one of HNO₃ or H₂O₂ to the solutions to tune an etch property of the wet etching.

8. The method of claim 4, wherein the solution comprising the second etchant includes a mixture containing an organic acid as an active ingredient.

9. The method of claim 8, wherein the mixture comprises an aqueous mixture of at least one of citric acid or phosphoric acid.

10. The method of claim 4, wherein the layers comprise a doping profile that increases the preferential etching:
of the first etchant, increasing the etch rate of the AlₓGa₁₋ₓN as compared to the Al_{y}Ga_{1-y}N when x is less than y, or
of the second etchant, increasing the etch rate of the AlₓGa₁₋ₓN as compared to the Al_{y}Ga_{1-y}N when x is greater than y.

11. The method of claim 4, comprising:
obtaining the III-Nitride N-polar layers comprising a nitride barrier layer comprising aluminum, a GaN channel layer on or above the nitride barrier layer; a nitride cap layer comprising aluminum on or above the GaN channel layer; and a GaN cap layer on or above the nitride cap layer; and
etching one or more of the layers, comprising wet etching using one or more solutions comprising at least one of the first etchant or the second etchant.

12. The method of claim 11, wherein:
the device comprises a high electron mobility transistor, and
the method further comprises depositing an etch mask on the GaN cap layer,
the wet etching etches the recess comprising a gate recess through the GaN cap layer, forming a lateral undercut in the etch mask, and
the method further comprises depositing gate metal in the gate recess, wherein the lateral undercut allows deposition of the gate metal in a self-aligned manner and reduces or eliminates deposition of the gate metal on sidewalls of the GaN cap layer.

13. The method of claim 11, wherein:
the device comprises a high electron mobility transistor, and
the wet etching etches at least one of:
a recess through part of the GaN cap layer that does not expose the nitride cap layer
a recess through the GaN cap layer that exposes the nitride cap layer, or
a thickness through the GaN cap layer and the nitride cap layer so as to expose the GaN channel layer.

14. The method of claim 13, wherein the wet etching forms the gate recess exposing a wet etched surface of the nitride cap layer, the method further comprising:
depositing gate metal on the wet etched surface so as to form an electrical interface with the wet etched surface, the electrical interface comprising a Schottky barrier, the electrical interface comprising at least one of:
a higher Schottky barrier height by 0.1 eV or more or
a reduced gate leakage by a factor of 10 or more,
relative to a dry-etched or non-wet-etch treated surface, and such that the gate metal forms a gate with an absolute gate leakage below 1 mA/mm at a drain voltage at or below 0.5 V and a gate voltage corresponding to 1 milliamp/millimeter of drain current .

15. The method of claim 14, wherein the gate metal comprises ruthenium metal or an alloy containing greater than 20% ruthenium metal and forms a barrier height greater than 0.6 eV to the nitride cap layer.

16. The method of claim 13, wherein the wet etching forms the recess comprising a gate recess and exposes an N-polar wet etched surface of the nitride cap layer, the method further comprising:
depositing a dielectric layer in the recess and on the nitride cap layer, wherein an electrical N-polar-dielectric interface, between the dielectric layer and the N-polar wet etched surface, has a reduced number of interface states by a factor of 2 or more as compared to when the interface is formed using dry etching and with an overall density of interface states below 5×10¹² cm⁻²eV⁻¹.

17. The method of claim 12, wherein the wet etching etches a thickness of the GaN cap layer so that the GaN cap layer is thinner on one side of the gate recess than the other.

18. The method claim 17, comprising a T-shaped gate metal in the recess and wherein the T-shaped gate metal is used as a mask during the wet etching.

19. A diode or transistor device, comprising:
an N-polar group III-nitride semiconductor; and
a conductive material on or above the semiconductor and forming an interface between the conductive material and the N-polar group III-nitride semiconductor, wherein:
a barrier height comprising a conduction band difference between the N-polar III-nitride semiconductor and the conductive material at/near the interface is larger than the difference between the work function of the conductive material and the electron affinity of the N-polar group III-Nitride semiconductor, wherein the conductive material forms a Schottky barrier between the semiconductor and the conductive material.

20. The device of claim 19, wherein the conductive material comprises ruthenium metal or an alloy containing greater than 20% ruthenium metal and forms a barrier height greater than 0.6 eV to the N-polar III-nitride semiconductor.
